(19) United States
(12) Patent Application Publication
(10) Pub. No.: US 2012/0048329 A1
(43) Pub. Date: Mar. 1, 2012

(54) CHARGE-COUPLED PHOTOVOLTAIC DEVICES

(76) Inventor: Lalita Manchanda, Dana Point, CA (US)

(21) Appl. No.: 13/152,211

(22) Filed: Jun. 2, 2011

(51) Int. Cl. H01L 31/042; H01L 31/06

(52) U.S. Cl. 136/244; 136/255

(57) ABSTRACT

A photovoltaic (solar) cell comprises two photovoltaic devices that are quantum mechanically coupled via a charge-coupling layer. One of the PV devices may have an energy band gap that is larger than or equal to an energy band gap of the other of the PV devices. The effective electron barrier heights or electron affinity on side portions of the quantum coupling layer are higher than the maximum energy of photo-generated electrons in the photovoltaic devices. The photovoltaic device with larger band gap may include an electron and/or hole transport layer and photon absorbing layer. Photons are transmitted through the transport layer to the absorbing layer. Some high energy photons are absorbed by the absorbing layer. The absorbing layer may function as an absorber of high energy photons and generator of electrons/holes (or excitons). Holes generated in the absorbing layer may be quenched by electrons from the second photovoltaic device.

### BACKGROUND OF THE INVENTION

The photovoltaic effect may be used to convert sunlight (photons) to electricity. When photons strike a photovoltaic, solar device, or cell (e.g., a or series of semiconductor p-n junctions), photons may be partially absorbed and partially reflected. Absorption of photons by a solar cell may result in generation of electron-hole pairs (EHP). EHPs, once separated across a p-n junction or band-offsets, result in the generation of voltage which may generate current in an external load. Therefore, power may be extracted from the photovoltaic device.

Solar or photovoltaic cells (also “cells” herein) may be configured in arrays to make solar cell systems (also “modules” herein). The net power generation from a module is directly proportional to the efficiency (η) of the solar cell. This efficiency may depend on the fundamental properties of the photon absorbing and electron transporting layers, cell design configured for electrons paths, and the technology used to fabricate cells.

With efficiency and cost being the drivers of the photovoltaic industry since the 1950s, with the invention of single crystal silicon solar cell, there have been various solar cell designs and technologies to increase the efficiency and decrease the module cost. These technologies may include bulk silicon solar cells and thin film solar cells.

Bulk silicon (“silicon”) solar cells are single or multi junctions with front and/or back contacts. Depending on the crystalline size and the nature of forming the starting substrate, these may be further divided into three categories, mono crystalline silicon, poly or multi-crystalline silicon, and ribbon silicon. Among the silicon solar cells, the highest efficiency has been achieved with single crystal silicon, with current design theoretical cell efficiency limit of about 29%, lab level efficiency of about 25% and module level of about 18%. See, e.g., Green et al., “Solar Cell Efficiency Tables”, Progress in Photovoltaics Research and Applications, V17, p 85 (2009); M. A. Green, “The path to 25% Silicon Solar Cell Efficiency”, Progress in Photovoltaics Research and Applications, V17, p 183 (2009); and Yoon et al., Ultra-thin silicon solar micro cells”, Nature Materials, V7, p 909 (2008), which are entirely incorporated herein by reference. These solar cells have a high figure of merit, i.e., efficiency multipled by reliability divided by cost (i.e., η×R/C). While, emerging nanowire silicon is also a bulk silicon technology, the η×R/C trend of this technology has yet to be established. See, e.g., Kelzenberg et al., “Enhanced absorption and carrier collection in Si wire arrays for photovoltaic applications”, Nature Materials, V9, p 239 (2010), which is entirely incorporated herein by reference.

Thin Films solar cells may have thicknesses less than about 10 micrometers (“μm”). There are various types of thin film solar cells. “High end” solar cells may achieve efficiencies higher than the theoretical limiting efficiency of single crystal silicon solar cells. High end thin film solar cells may include, for example, multi junction gallium arsenide (GaAs) cells, indium phosphide (InP) cells, and metamorphic cells. See, e.g., King et al., “40% Efficient Metamorphic GaInP/GaInAs/Ge multi junction solar cells”, Applied Physics Letters, V90, p 183516 (2007), which is entirely incorporated herein by reference. These are expensive technologies with market limited to space applications and the emerging CPV systems. The other end of the thin film technologies is to reduce the cost of starting substrate to much less than the crystalline silicon technologies. Such thin film solar cells may include, for example, amorphous silicon, micromorph, copper indium gallium (di)selenide (CIGS) solar cells and cadmium tellurium (CdTe) solar cells. See, e.g., Green et al., “Solar Cell Efficiency Tables”, Progress in Photovoltaics Research and Applications, V 17, p 85 (2009), which is entirely incorporated herein by reference. These technologies have advantages of direct band gap. The CIGS and the CdTe are approaching the efficiency to 16-18%. However, scarcity of the available raw materials and the toxicity of Cd may make it difficult to capture large scale markets. Amorphous silicon is not expensive and has technological advantages, such as leveraging processes developed for other semiconductor-containing devices (e.g., chips). One drawback of amorphous silicon is that it does not have a very high efficiency and light induced degradation reduces the figure of merit for amorphous and micromorph technologies. Another class of thin film technologies is the organic solar cells. In this category, the dye-sensitized solar cells (DSC) are “leapfrogging” the cost reduction trend. However, chemical instability is a bottleneck to put it in the market place. Such technology may benefit from a solid state, low cost solution. See, e.g., B. O'Regan and M. A. Gratzel, “A high efficiency solar cell based on dye sensitized colloidal TiO₂ films”, Nature 353, p 737 (1991); Bai et al., “High performance dye-sensitized solar cells based on solvent-free electrolytes produced from eutectic melts”, Nature Materials, V7, p 626 (2008); Cao et al., “Engineering light absorption in semiconductor nanowire devices”, Nature Materials, online publication, Jul. 5, 2009; and Fan et al., “Three Dimensional nano pillar array photovoltaics on low cost and flexible substrates”, Nature Materials, p 1 (2009), which are entirely incorporated herein by reference.

In spite of numerous materials/designs/technologies inventions/innovations, bulk silicon modules (single crystal silicon now and ongoing transition to multi-crystal silicon) currently have about 80% of the solid state solar panel market. Silicon being the base material of semiconductor industry, bulk silicon modules have the highest reliability and therefore dominate the market. However, the fundamental and technology related losses have limited the maximum achieved cell efficiency to about 25% at the lab level and about 18% at the industry (or module) level. See, e.g., Green et al., “Solar Cell Efficiency Tables”, Progress in Photovoltaics Research and Applications, V17, p 85 (2009); and M. A. Green, “The path to 25% Silicon Solar Cell Efficiency”, Progress in Photovoltaics Research and Applications, V17, p 183 (2009), which are entirely incorporated herein by reference.

Current solar cells suffer from other limitations, such as energy losses (or losses). There are fundamental (e.g., materials characteristics) and technology (design, fabrication) related losses associated with photons striking a solar cell. Loss by reflection is a technology or design related loss where part of the incident photon flux is reflected by the device surface. See, e.g., E. Yablonovitch and G. D. Cody, “Intensity enhancement in textured optical sheets for solar cells”, IEEE Trans. on Electron Devices, V29, p 300, (1982), which is entirely incorporated herein by reference. Loss due to incomplete absorption is also a technology or design related loss due to the limited thickness and large wavelength photons not being completely absorbed. Loss due to metal coverage is a design-related loss and depends on the cell front and back metal coverage. Loss due to fill factor is due to series or shunt resistance of the cell. Voltage loss is due to the fact that the open circuit voltage (VOC) depends on the band gap of the semiconductor, the junction potential or the band offsets of the absorbing and electron transport layers.

Other losses that may limit solar cell efficiency include transmission losses, thermalisation loss and recombination losses.

Transmission loss includes loss of low energy photons. In transmission losses, photons having energy less than the band gap of the semiconductor or ionization potential of the absorbing layer do not get absorbed in the material and therefore do not contribute to the photocurrent. For silicon crystalline solar cell, this loss is about 23%.

Thermalisation loss includes loss due to excess energy of photons. In thermalisation loss, to generate photon induced electrons, theoretically, photon energy should be equal to the energy of the band gap, E_{g}. When the part of the incident photon spectrum has energy greater than E_{g}, the excess energy E-E_{g} is lost due to heat to the material. For crystalline single junction silicon cells, this loss, which may be a combination of incomplete energy transfer to the load and reduction of photocurrent due to increase of the junction temperature, may be about 31%.

Recombination loss includes loss due to generated charge carriers (electrons, holes) recombining at an interface or the bulk of a semiconductor material. Bulk recombination loss may be minimized by improving the carrier lifetime in the semiconductor.

Silicon is a lead material of semiconductor industry. While very high lifetime substrates are available, high lifetime silicon substrates are very expensive. Interface and bulk recombination loss therefore remains to be a major technology challenge for silicon and other solar cell technologies.

### SUMMARY OF THE INVENTION

In an aspect of the invention, a photovoltaic solar cell (also “photovoltaic” herein) device invokes a device structure with charge coupling by quantum tunneling through an insulator to reduce losses, such as thermalisation, recombination and reflection losses.

In an embodiment, a photovoltaic solar cell (“cell”) structure includes a first photovoltaic device (device I) of effective band gap E_{I} electron volts (“eV”) disposed over a second photovoltaic device (device II) with band gap E_{II} eV. In one embodiment, E_{I} may be greater than or equal to E_{II}. The first photovoltaic device of band gap E_{I} is quantum mechanically coupled to the second photovoltaic device with band gap E_{II}.

The first photovoltaic device may be quantum mechanically coupled to the second photovoltaic device through at least one charge coupling (or quantum coupling) layer between device I and device II. When light falls on device I, it may absorb a spectrum of light with energy (hν) greater than E_{I}, and electrons/holes (or excitons) are generated. Unabsorbed photons pass through device I and the quantum coupling layer to device II, at which point they may generate further carriers. The quantum charge coupling between these two devices is done with a tunneling insulator layer. Low energy carriers/charge tunnel from device II to device Ito quench light-generated positive charges (holes or ions) in device I.

The cell may include one or more charge coupling layers. For example, the cell may include at least 1, or 2, or 3, or 4, or 5, or 6, or 7, or 8, or 9, or 10, or 50, or 100 layers. Each individual layer may be formed of a charge coupling material. In some cases, a subset of a stack of charge coupling layers is formed of a charge coupling material.

Device I may be a semiconductor which generates and transports electrons. Device I may include a semiconductor material for transporting electrons, which may be placed on (or intermixed with) a high quantum efficiency material that is used to absorb photons having energies greater than E_{I}. Unabsorbed light may be transmitted through the coupling layer to a semiconductor device below (device II) having an effective band gap E_{II}. The quantum coupling layer between device I and II may be an insulator. The quantum coupling layer, which may provide tunneling through the insulator, may couple electrons from the device II to holes or fixed charge in device I. The device I, the quantum coupling layer and the device II may function as electrically active layers. The device I and the quantum coupling layer may also function as antireflection coating to device II.

A photovoltaic cell may include a device structure having device I, the quantum coupling layer adjacent device I, and device II adjacent the quantum coupling layer. Device I may include two material layers, layer I-I and layer I-II, layer I-I having an electron transport semiconductor and layer I-II having a high efficiency photon absorbing material.

E_{I} may be greater than or equal to E_{I-II}. In some situations, E_{I-I} may be greater than E_{I-II}. Light incident on the photovoltaic device may pass through the transport semiconductor layer to layer I-II, which may absorb photons with energy greater than or equal to E_{I-II}. The remainder of the energy is transferred through this layer and the quantum coupling layer to device II, where further carriers are generated. The coupling layer couples electrons from device II to device I and quenches the positive charges generated in the absorbing layer I-II. The device I absorbs high energy photons and transports high energy carriers and reduces the generation of high carriers in device II and thus reduces the thermalisation loss in device II and increases the net efficiency. Also, by reducing the generation of high energy electrons in device II, the net heat generation in device II may be reduced and the operating efficiency of device II may be improved, providing for further reduction of the thermalisation loss. The layers I-I and I-II may be two separate layers and/or intermixed with band gaps E_{I-I} and E_{I-II}, wherein E_{I-I} may be greater than or equal to E_{I-II}. In some situations, E_{I-I} may be greater than E_{I-II}.

In some embodiments, the absorbing layer I-II may be made of a thin semiconductor layer, semiconductor quantum dots or semiconductor quantum wells or a combination of all three.

In another embodiment of the invention, layer I-II may be an absorbing layer for absorbing high energy photons. Layer I-II may be formed of a multi spectrum dye on a semiconductor layer, dyes absorbed in the semiconductor layer, a dye placed directly on the coupling layer and/or quantum dots made with dye.

Device I may include one or more charge coupling layers. For example, device I may include at least 1, or 2, or 3, or 4, or 5, or 6, or 7, or 8, or 9, or 10, or 50, or 100 layers. Each individual layer may be formed of a charge coupling material. In some cases, a subset of a stack of charge coupling layers is formed of a charge coupling material.

Device II may be formed of one or more semiconductors with single or multi-junctions. The second photovoltaic device may be formed of one or more semiconductors and/or semi-insulators. Device II may be a single/multi-junction silicon solar cell (e.g., single crystal, multi crystal, ribbon, Epi, thin film or nanowire). This device may be designed as N+/P, N+/P/P+, N+/I/P, P/N+PERC, PERL, Tandem configuration, etc. The quantum coupling layer may be formed of a silicon oxide, such as silicon dioxide or silicon rich oxide, a silicon nitride, or silicon oxynitride. The thickness of this insulator may be less than 2 nm for direct quantum tunneling or greater than about 2 nm for Fowler Nordheim tunneling. The source of electrons for quantum coupling may be carriers returned from the device I via the load and/or carriers generated in the device II and the carriers trapped in the silicon-insulator interface or regime near the interface. In the preferred embodiment of the invention, the absorbing layer I-II is made of a thin layer of silicon (amorphous or nanocrystal or nanowire); silicon quantum dots embedded in the material of the transport layer and/or the coupling layer; or silicon quantum wells. In the preferred embodiment of the invention, the electron transport layer I-I is an n-type semiconductor with band gap greater than 2.5 eV (e.g., oxide of titanium and/or its alloys). The second photovoltaic device has one or more semiconductors with single or multi-junction. Device II may also contain heavily doped semiconductors (e.g., n+, p+ silicon), metal layers or conducting oxides, etc.).

A photovoltaic device may have a three dimensional topography to increase the absorption coefficient in the device I and device II and to decrease the electron transfer loss in the transport layer. Such topography may include a corrugated surface having variously oriented crystallographic facets. The three dimensional structure may be a V-Groove or Via or Cylinder shape or random rough surface with aspect ratio optimized for maximum photon absorption and to keep the electric field on the coupling layer less than the breakdown strength of the coupling insulator. The three dimensional structure reduces reflection (improves the photon absorption), increases quantum charge coupling and reduces the effective amount of silicon/semiconductor used to make the device II.

In some cases, device II may be replaced by a conducting layer or layers (metal, metal alloy, metal oxide, highly doped semiconductor). The quantum coupling layer may be a metal oxide (e.g., Aluminum Oxide). The transport layer I-I may be an n-type semiconductor, e.g., oxide of titanium or its alloys. The absorbing layer I-II may be a photon absorbing layer, e.g., dye and/ or QDs of dye and/or semiconductor layers and/or QDS of semiconductors or dyes absorbed in the semiconductor layers. In such a case, the absorption layer may include multi-layer dyes to absorb photons with energy greater than 0.6 eV. The unabsorbed photons may be reflected by the metal and will be absorbed by the absorbing layer and contribute to the active current/power. The layers I-I and I-II may be two separate layers or intermixed with band gaps E_{I-I} and E_{I-II}, wherein E_{I-I} may be greater than or equal to E_{I-II}. In some situations, E_{I-I} may be greater than E_{I-II}. Device II may be formed in a three-dimensional (“3D”) configuration to increase photon absorption and increase the active power.

Device I may be formed of one or more charge coupling layers. In some cases, Device I and Device II may be formed in a 3D configuration, which may increase photon absorption.

In some embodiments, an array of photovoltaic (or solar) cells includes a plurality of photovoltaic cells. Solar cell arrays provided herein may be configured such that individual solar cells are floating or connected to one another in a parallel or serial arrangement. In such a case, a TCO/metal contact on top and/or bottom of photovoltaic cells in the array may be connected with devices I and II in each cell either in a serial or parallel arrangement. This configuration may be optimized for delivering maximum power to the module load/loads.

In another embodiment, a photovoltaic (“PV”) cell comprises a first photovoltaic device having a first energy band gap; a charge-coupling layer adjacent the first photovoltaic device; and a second photovoltaic device adjacent the charge coupling layer, the second photovoltaic device having a second energy band gap. Such PV cells may be electrical coupled to one another in series or parallel to form PV modules.

In another embodiment, a photovoltaic cell comprises a first photovoltaic device having a light transmission layer adjacent a photon absorption layer, the photon absorption layer for generating charge upon exposure to photons; and a quantum coupling layer adjacent the first photovoltaic device, the quantum coupling layer for coupling charge in a metal layer or second photovoltaic device adjacent the quantum coupling layer to charge in the absorption layer.

In another aspect of the invention, a photovoltaic cell array comprises a plurality of photovoltaic cells, each individual photovoltaic cell of the plurality of photovoltaic cells comprising a first photovoltaic device having a first energy band gap, at least one charge-coupling layer adjacent the first photovoltaic device, and a second and/or third photovoltaic device adjacent the charge coupling layer, the second and/or third photovoltaic device having a second and/or third energy band gap. The plurality of photovoltaic cells may be electrically floating cells or interconnected in series or parallel. In an example, the second photovoltaic device is adjacent the charge coupling layer and the third photovoltaic device is adjacent the charge coupling layer and adjacent the second photovoltaic device.

In another aspect of the invention, a method for forming a photovoltaic cell comprises forming a first photovoltaic device adjacent a charge-coupling layer, the charge-coupling layer formed adjacent a second photovoltaic device, wherein the charge-coupling layer is for coupling charge in the second photovoltaic device to charge in the first photovoltaic device.

In another aspect of the invention, a photovoltaic cell formed according to the methods provided herein is described.

In another aspect of the invention, photovoltaic cells comprising one or more charge-coupled photovoltaic devices are provided. In some embodiments, a photovoltaic cell comprises a charge-coupled photovoltaic device. In other embodiments, a photovoltaic cell comprises a first photovoltaic device charge-coupled to a second photovoltaic device. In other embodiments, a photovoltaic cell comprises a photovoltaic device charge-coupled to an electrically conductive layer. In an embodiment, the electrically conductive layer is formed of one or more metals.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 is a schematic cross-sectional side view of a photovoltaic (“PV”) cell having a first PV device and second PV device separated by a quantum coupling layer (“QCL”), in accordance with an embodiment of the invention;

FIG. 2 is a schematic cross-sectional side view of a PV cell having a first PV device and second PV device separated by a QCL, in accordance with an embodiment of the invention. The first PV device includes a first layer adjacent a second layer;

FIG. 3 schematically illustrates an energy band diagram for a photovoltaic cell having a first PV device and second PV device separated by a QCL, in accordance with an embodiment of the invention;

FIG. 4 schematically illustrates an energy band diagram for a photovoltaic cell having a first PV device and second PV device separated by a QCL, in accordance with an embodiment of the invention;

FIG. 5 schematically illustrates an energy band diagram of barrier heights and electron affinities of a first layer (Layer I-I) and second layer (Layer I-II) of a first PV device (Device I), a coupling layer, and a second PV device (Device II), in accordance with an embodiment of the invention. In the illustrated embodiment, χ_{I-I-II}≦e_{maxI-II}≦χ_{I-II-C}≦χ_{C-II-I}, and e_{maxI-II} is the difference between the maximum energy of the absorbed photons and the band gap or the excitation potential of layer I-II;

FIG. 6 schematically illustrates an energy band diagram of the coupling of charges from a second PV device (Device II) to a second layer (Layer I-II) of a first PV device (Device I), in accordance with an embodiment of the invention;

FIGS. 7A-7D are schematic cross-sectional side views of a PV cell having an absorption layer (Layer I-II) formed of various materials, in accordance with various embodiments of the invention;

FIGS. 8A-8C are schematic cross-sectional side views of a PV cell having an absorption layer (Layer I-II) formed of various materials, in accordance with various embodiments of the invention;

FIGS. 9A-9E are schematic cross-sectional side views of a PV cell having three-dimensional structures, in accordance with an embodiment of the invention;

FIGS. 10A and 10B are schematic cross-sectional side views of cells for front and back-lighted modules, in accordance with various embodiments of the invention;

FIG. 11A is a schematic cross-sectional side view of a PV cell having a PV device adjacent a QCL and a metal layer adjacent the QCL, in accordance with an embodiment of the invention. FIG. 11B is an energy band diagram of the PV cell of FIG. 11A, in accordance with an embodiment of the invention; and

FIG. 12 shows a method for forming a PV module having a first PV device, charge-coupling layer and second PV device, in accordance with an embodiment of the invention. The PV cell is configured to accept light initially from the direction of the second PV device.

### DETAILED DESCRIPTION OF THE INVENTION

While preferable embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

Photovoltaic devices and cells described various embodiments of the invention may improve charge generation and retention over current devices and cells. Photovoltaic cells described in various embodiments may advantageously increase the amount of charge generated per given quantity of light incident on a photovoltaic device. Photovoltaic cells may minimize thermalisation and recombination losses associated with current photovoltaic devices. Photovoltaic modules may provide for generating more electricity in a clean and sustainable fashion.

The term “cell,” as used herein, refers to a separable or interchangeable component, such as a photovoltaic solar cell. A cell may include one or more photo-active (or photovoltaic) devices, which may include one or more layers of a photo-active material.

The term “module,” as used herein, refers to an array of cells or solar cells. In some situations, one type of cell may be used to form a module. In other situations, a module may include different types of cells. A photovoltaic module may include one or more separable or interchangeable components, such as photovoltaic cells. In some cases, a photovoltaic module may include a photovoltaic cell adjacent another photovoltaic cell. A cell in a module may be electrically connected to one or more other cells (or modules) in series or parallel.

The term “surface,” as used herein, designates an interface between a first phase and a second phase. In one embodiment, a surface may designate an interface of a first solid phase and second solid phase. In another embodiment, a surface may designate an interface of a solid or liquid phase and a liquid or gas phase. For example, a surface may be disposed at a top-most atomic layer of a semiconductor (or semiconductor-containing) material. The surface in such a case may be in contact with a vapor or liquid, or another solid, such as another semiconductor (or semiconductor-containing) material.

The term “layer,” as used herein, designates a device or structure having one or more atomic layers. For example, a layer of semiconductor material may include one atomic layer of semiconductor material or multiple atomic layers of semiconductor material. In one embodiment, a layer is a monoatomic monolayer (“ML”) or single atomic layer of a material. In another embodiment, a layer includes multiple atomic layers of a material. For example, a layer may include at least 1, or at least 10, or at least 100, or at least 1000, or at least 10,000, or at least 100,000, or at least 1,000,000, or at least 10,000,000 atomic layers.

The term “material property,” as used herein, refers to physical, electronic and optical properties of a material, such as a thin film, layer or substrate. A material property may be selected from the chemical composition of a material, the energy band gap of the material, the size (height, width, length) of the material, the thickness of the material, the doping concentration of the material, the surface roughness of the material, the defect density of the material.

The term “adjacent,” as used herein, means next to or adjoining. A layer, device or structure adjacent another layer, device or structure is next to or adjoining the other layer, device or structure. In an example, a first photovoltaic device that is adjacent a second photovoltaic device is directly next to the second photovoltaic device.

It will be appreciated that the terms “first” and “second”, as used herein, may be employed in a naming convention for the purpose of describing features of devices provided herein. Such terms are intended to be illustrative and do not necessarily indicate the order in which various features are formed. For example, a photovoltaic cell having a first photovoltaic device adjacent a second photovoltaic device may be formed by first forming the first photovoltaic device followed by the second photovoltaic device, or by first forming the second photovoltaic device followed by the first photovoltaic device.

### Photovoltaic Cells and Devices

In an aspect of the invention, a photovoltaic cell is provided including a first photovoltaic device, a charge-coupling layer adjacent the first photovoltaic device, and a second photovoltaic device adjacent the charge-coupling layer.

In embodiments, the charge-coupling layer may include an electrically insulating material for providing charge-coupling between the first and second photovoltaic devices. In one embodiment, the electrically insulating material is a dielectric material having a band gap greater than about 0 electron volts (“eV”), or greater than or equal to about 0.1 eV, or 0.2 eV, or 0.5 eV, or 1 eV, or 2 eV, or 5 eV, or 10 eV. In some situations, the charge-coupling (or quantum coupling layer) may have a band gap between about 4 eV and 10 eV, which may be greater than E_{I-I}

The charge-coupling layer may provide quantum mechanical coupling between the first and second photovoltaic devices. In another embodiment, the charge-coupling layer enables Fowler-Nordheim tunneling (e.g., field electron emission) between the photovoltaic devices and across the charge-coupling layer.

Charge coupling layer-containing photovoltaic devices may have efficiencies (η) of at least about 5%, or 6%, or 7%, or 8%, or 9%, or 10%, or 11%, or 12%, or 13%, or 14%, or 15%, or 16%, or 17%, or 18%, or 19%, or 20%, or 21%, or 22%, or 23%, or 24%, or 25%, or 26%, or 27%, or 28%, or 29%, or 30%, or 31%, or 32%, or 33%, or 34%, or 35%, or 36%, or 37%, or 38%, or 39%, or 40%, or 41%, or 42%, or 43%, or 44%, or 45%, or 46%, or 47%, or 48%, or 49%, or 50%. In some cases, for a photovoltaic device having a band gap greater than or equal to about 1.1 eV (e.g., a silicon-based PV device), the cell efficiency may be greater than about 67%, or 68%, or 69%, or 70%, or 71%, or 72%, or 73%, or 74%, or 75%, or 76%, or 77%. For a photovoltaic device having a band gap less than about 1.1 eV (e.g., a germanium-based PV device), the cell efficiency may be greater than about 70%, or greater than about 85%, or greater than about 80%, or greater than about 85%, or greater than about 90%.

Reference will now be made to the figures. It will be appreciated that the figures are not necessarily drawn to scale.

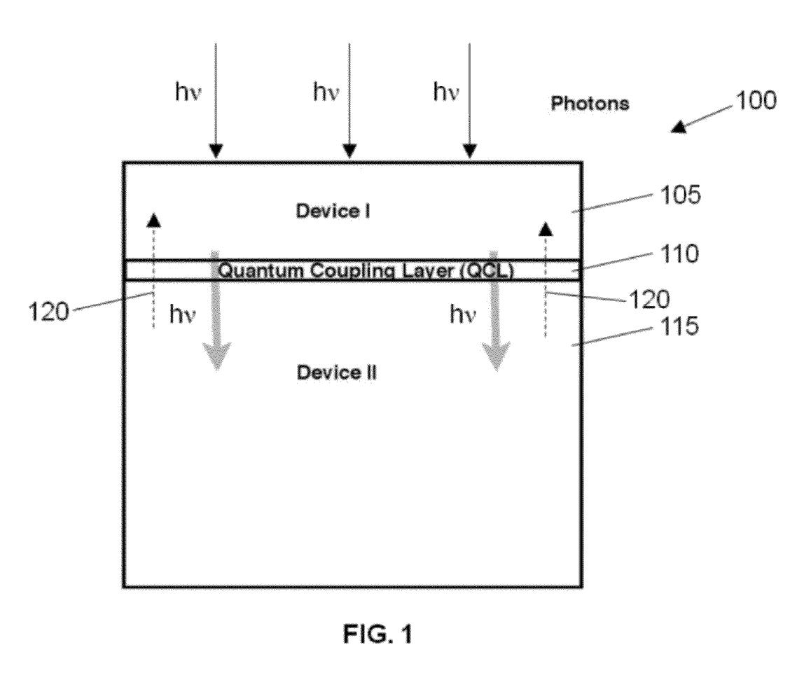

With reference to FIG. 1, a photovoltaic cell 100 is illustrated, in accordance with an embodiment of the invention. The cell 100 includes a first photovoltaic (“PV”) device 105 (“Device I”), a quantum coupling layer (“QCL”) (also “charge-coupling layer” herein) 110, and a second photovoltaic device 115 (“Device II”). The arrows indicate the direction in which photons (hν) enter the cell 100 and propagate through the photovoltaic devices 105 and 115 of the cell 100. Photons are transmitted and absorbed by the first photovoltaic device 105 and then transmitted through the charge-coupling insulator 110 to the second photovoltaic device 115.

With continued reference to FIG. 1, the photovoltaic devices 105 and 115 are configured to generate electricity upon exposure to light (or photons). In one embodiment, upon a given quantity of light striking the cell 100 (at the side of the first photovoltaic device 105), a fraction of the light may be transmitted through the first photovoltaic device 105 to the charge-coupling layer 110 and the second photovoltaic device 115, a fraction of the light may be absorbed by the first photovoltaic device 105 to generate electricity (electrons), and a fraction of the light may be reflected away from the cell 100. In addition, a portion of the light incident on the cell 100 may generate heat in the module.

In one embodiment, the charge-coupling layer 110 is a quantum (or quantum mechanical) coupling layer. In another embodiment, the charge-coupling layer 110 is an electron emission coupling layer.

The first photovoltaic device 105 may have a thickness greater than about one monolayer (ML). In some cases, the first PV device 105 may have a thickness greater than or equal to about 1 nanometer (“nm”), or 2 nm, or 5 nm, or 10 nm, or 20 nm, or 50 nm, or 100 nm, or 200 nm, or 500 nm, or 1000 nm, or 2000 nm, or 5000 nm, or 10,000 nm. In some situations, the first PV device 105 may have a thickness between about 50 nm and 1000 nm, or 100 nm and 500 nm.

In one embodiment, the charge-coupling layer 110 may have a thickness greater than 1 nanometer (“nm”), or 2 nm, or 3 nm, or 4 nm, or 5 nm, or 6 nm, or 7 nm, or 8 nm, or 9 nm, or 10 nm, or 20 nm, or 30 nm, or 40 nm, or 50 nm, or 100 nm. In another embodiment, the charge-coupling layer 110 may have a thickness between about 1 nm and 100 nm, or 1.5 nm and 50 nm, or 2 nm and 10 nm.

The second photovoltaic device 115 may have a thickness greater than about 1 ML. In some situations, the second PV device 115 may have a thickness greater than or equal to about 1 nm, or 2 nm, or 5 nm, or 10 nm, or 20 nm, or 50 nm, or 100 nm, or 200 nm, or 500 nm, or 1000 nm, or 2000 nm, or 5000 nm, or 10,000 nm, or 20 micrometer (“μm”), or 100 μm, or 200 μm, or 500 μm. In other situations, the PV device 115 may have a thickness between about 5 nm and 500 μM, or 10 nm and 100 μm. The second photovoltaic device 115 may have a thickness that is greater than about Y multiplied by the number of Debye Lengths (D) multiplied by the number (N) of n-p or p-n junctions across an electric path of the second photovoltaic device 215, i.e., Y×D×N (‘x’ designates the multiplication operator), where ‘Y’ is a number greater than or equal to 0.In one embodiment, the second photovoltaic device 215 has a thickness greater than or equal to about 0.5×D×N, or greater than or equal to about 1×D×N, or greater than or equal to about 2×D×N, or greater than or equal to about 3×D×N, or greater than or equal to about 4×D×N, or greater than or equal to about 5×D×N, or greater than or equal to about 6×D×N, or greater than or equal to about 7×D×N, or greater than or equal to about 8×D×N, or greater than or equal to about 9×D×N, or greater than or equal to about 10×D×N, or greater than or equal to about 100×D×N, or greater than or equal to about 1000×D×N.

In one embodiment, the first photovoltaic device 105 may be formed of one or both of a semiconductor material and semi-insulating material. A semiconductor material may be selected from Group IV, IV-IV, III-V, II-VI, III-VI semiconductors, such as silicon, germanium, gallium arsenide and indium gallium nitride. A semi-insulating material may be selected from gallium nitride, metal-rich metal oxides (e.g., TiₓO_{y}, ZnₓO_{y}, etc.) or silicon oxides (e.g., SiₓO_{y}), such as silicon-rich silicon oxides. In another embodiment, the first photovoltaic device 105 may be formed of a Group IV semiconductor, such as one or more of silicon and germanium. In another embodiment, the first photovoltaic device 105 may be formed of a Group III-V material selected from aluminum, gallium, indium, nitrogen, phosphorous, arsenic, such as, for example, aluminum phosphide, aluminum arsenide, gallium arsenide, or gallium nitride. The second PV device 105 may be formed of a semiconductor or semi-insulator.

In one embodiment, the charge-coupling layer (also “quantum coupling layer” herein) 110 may be formed of an electrically insulating or semi-insulating material (also “insulator” herein). An insulating material may be selected from any dielectric material, such as a metal oxide (e.g., TiOₓ, SiOₓ), or composite material, which may include one or more of a metal, semiconductor or polymeric material. In another embodiment, the charge-coupling layer 110 may be formed of an oxide or oxynitride of a Group IV semiconductor. In another embodiment, the charge-coupling layer 110 may be formed of an oxide or oxynitride of a Group III-V material. The charge-coupling layer 110 may be formed of an insulator or semi-insulator.

In one embodiment, charge-coupling layer 110 may have a dielectric constant greater than about 1, or 2, or 3, or 4, or 5, or 6, or 7, or 8, or 9, or 10, or 20, or 30, or 40, or 50, or 60, or 70, or 80, or 90, or 100. In some cases, the charge-coupling layer 110 may have a dielectric constant between about 1 and 20, or between about 2 and 10. The charge-coupling layer 110 may have a breakdown strength between about 1 mV/cm and 100 MV/cm, or between about 5 MV/cm and 10 MV/cm.

In one embodiment, the second photovoltaic device 115 may be formed of a semiconductor or semi-insulator material. In another embodiment, the second photovoltaic device 115 may be formed of a Group IV semiconductor, such as one or more of silicon and germanium. In another embodiment, the second photovoltaic device 115 may be formed of a Group III-V material selected from aluminum, gallium, indium, nitrogen, phosphorous, arsenic, such as, for example, aluminum phosphide, aluminum arsenide, gallium arsenide, or gallium nitride. The second photovoltaic device may be formed of a Group IV, IV-IV, II-VI, III-V, III-VI semiconductor or semi-insulator. In some situations, the second photovoltaic device may be formed of Group IV and/or III-V semiconductors.

In embodiments, surfaces of the first and second photovoltaic devices 105 and 115 may be in electrical contact with electrodes for forming an electric flow path (or electric circuit), thereby permitting electrons generated by the cell 100 to flow out of the cell 100. In one embodiment, the electrical contact between the surfaces of the first and second photovoltaic devices 105 and 115 and electrodes are ohmic contacts. In another embodiment, the electrical contact between the surfaces of the first and second photovoltaic devices 105 and 115 and electrodes are nearly ohmic contacts. In one embodiment, a surface of the first photovoltaic device 105 is in electrical contact with a first electrode. The first electrode may flow electrons generated in the first photovoltaic device 105 away from the first photovoltaic device 105. The first electrode may include a mesh to minimize the amount of light blocked by the first electrode. A surface of the second photovoltaic device 115 may be in contact with a second electrode. The first and second electrodes may be formed of a metallic or metal-containing material, such as material including one or more of aluminum, copper, iron, nickel, gold, silver, platinum, titanium, tungsten, chromium, vanadium, manganese, cobalt, zinc, zirconium, yttrium, ruthenium, rhodium, cadmium, hafnium, tantalum, rhenium and iridium. The first electrode may include material selected from one or more metals (e.g., Al, Cu, Ag, Au, Pt), conducting transparent oxides/ceramics (e.g., indium tin oxide, tin oxide, zinc oxide), conducting polymers, and combinations thereof. In some cases, the first electrode may include one or more of aluminum and indium tin oxide (ITO). In some situations, opposing surfaces of the second PV device 115 may be in contact with electrodes.

In other embodiments, a photovoltaic cell is provided having a first photovoltaic device adjacent a charge-coupling layer and a second photovoltaic device adjacent the charge-coupling layer, the first photovoltaic device having a plurality of layers. In one embodiment, the first photovoltaic device includes a first layer adjacent a second layer. The first layer may have an energy band gap greater than an energy band gap of the second layer. In another embodiment, the first photovoltaic device may include 2, or 3, or 4, or 5, or 6, or 7, or 8, or 9, or 10, or 11, or 12, or 13, or 14, or 15, or 16, or 17, or 18, or 19, or 20, or more layers. The layers may be provided in a stacked configuration (i.e., one layer adjacent another layer) or mixed (or intermixed) configuration.

With continued reference to FIG. 1, in one embodiment, the PV device 105 and the charge-coupling layer 110 may function as anti-reflection layers. The cell 100 may include an additional anti-reflection coating layer above the PV device 105. In some situations, the PV cell 100 may include an anti-reflective layer above the first PV device 105. The anti-reflective layer may be configured to prevent or minimize light from being reflected out of the PV cell 100. The anti-reflective coating layer may be formed of a dielectric anti-reflecting coating (DARC) material. In another embodiment, the anti-reflective coating layer may be formed of a nitride, such as, for example, silicon rich silicon oxynitride. In another embodiment, the PV module may include a layer of reflective material below the second PV device 115. The layer of reflective material is configured to reflect (or scatter) light passing through the second PV device 115 back into the second PV device 115, the QCL 110 and the first PV device 105. The reflective material may be formed of a semiconductor oxide, a metal oxide, or a metal and semiconductor-containing oxide. In some cases, the reflective material may be formed of silicon nitride, silicon oxynitride or titanium oxide.

With continued reference to FIG. 1, the QCL 110 permits light to pass from the first PV device 105 to the second PV device 115. The QCL couples 120 charge (e.g., electrons) in the second PV device 115 to charge (e.g., holes, positive charges) in the first PV device 105. In one embodiment, charge coupling may permit electrons in the second PV device 115 to quantum mechanically tunnel to the first PV device 105.

Alternatively, the PV cell 100 may include a layer 105 on the charge-coupling layer 110, the charge-coupling layer 110 disposed on the second PV device 115. One or both of the layer 105 and the charge-coupling layer 110 may be anti-reflective layers, configured to permit light to pass through the layers toward the second PV device 115, and reflect light leaving the second PV device 115 back to the second PV device 115. In such a case, the layer 105 may preclude any PV devices—that is, the layer 105 may serve only to reflect light back to the second PV device 115. In other cases, however, the layer 105 may include a PV device, and the QCL 110 may be an anti-reflective layer for reflecting light back to the second PV device 115.

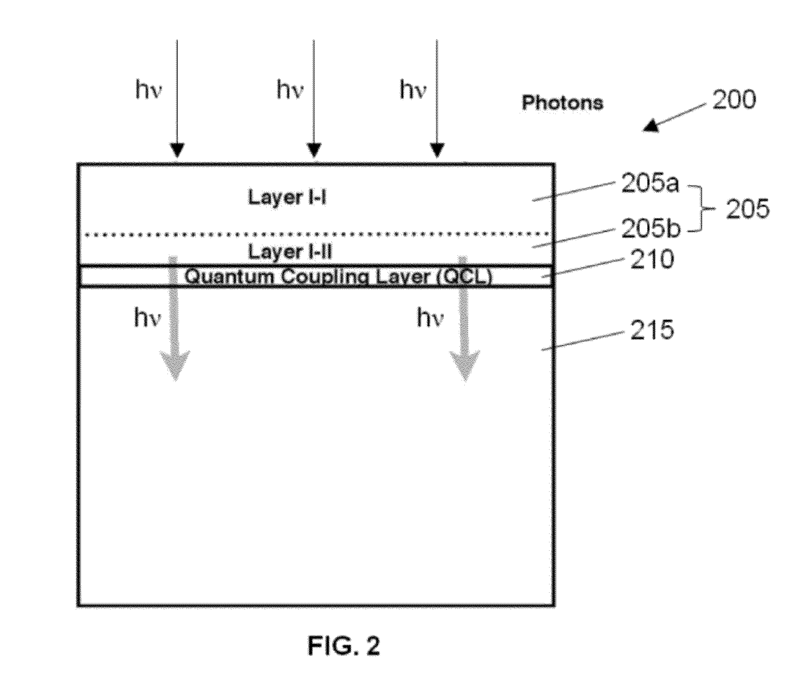

With reference to FIG. 2, a photovoltaic cell 200 is shown, in accordance with an embodiment of the invention. The photovoltaic cell 200 includes a first photovoltaic device 205, a charge-coupling layer 210 and a second photovoltaic device 215. The first photovoltaic device 205 includes a first layer 205a (“Layer I-I”) and a second layer 205b (“Layer I-II”). In one embodiment, the first layer 205a is a transport layer and the second layer 205b is an absorption layer, the transport layer for directing light to the absorption layer, the absorption layer for generating charge (e.g., electrons, holes) upon interaction with photons. In another embodiment, photons strike the first layer 205a and are transmitted through the first layer 205a to the second layer 205b, where high energy photons are absorbed to generate electrons and holes, or positive charges.

In some situations, the first photovoltaic device 205 may include one or more charge coupling layers. For instance, the first photovoltaic device 205 may include at least 1, or 2, or 3, or 4, or 5, or 6, or 7, or 8, or 9, or 10, or 50, or 100 charge coupling layers.

The charge-coupling layer 210 may be formed of one or more layers. For instance, the charge-coupling layer 210 may be formed of at least 1, or 2, or 3, or 4, or 5, or 6, or 7, or 8, or 9, or 10, or 50, or 100 layers. An individual layer may be a charge coupling layer.

In one embodiment, the absorption layer 205b may be formed of a semiconductor material and/or semi-insulator material with effective band gap greater than about 0 eV, or greater than or equal to about 0.1 eV, or 0.2 eV, or 0.5 eV, or 1 eV, or 2 eV, or 3 eV. In some situations, the absorption layer 205b may be formed of a semiconductor having an effective band gap greater than about 1.1 eV. In other situations, the absorption layer 205b may be formed of a semiconductor having an effective band gap between about 1.1 eV and 5 eV, or 1.2 eV and 3 eV.

The absorption layer 205b may include material selected from amorphous silicon, silicon nano-crystals, silicon nano-layers, quantum dots, or quantum wells (e.g., silicon quantum wells). In some cases, the absorption layer 205b may include a doped semiconductor material, such as an n-type or p-type semiconductor material. The absorption layer 205b may be a single layer, multilayer, or formed of an inter-mixed material.

The charge-coupling layer 210 may include silicon oxide, SiOx, wherein ‘x’ is a number greater than 0 (e.g., SiO₂ or silicon rich silicon dioxide), silicon oxynitride, or silicon nitride. In another embodiment, the charge-coupling layer 210 is an ion and/or impurity blocking layer blocks or impedes the flow of ions and/or impurity between the first PV device 205 and second PV device 215.

In one embodiment, electrons travel to an electrode in contact with a surface of the first photovoltaic device 205. In one embodiment, electrons generated in the second layer 205b are transported to a load in electrical communication with the cell 200 via the first layer 205a. Any unabsorbed photons transmitted through the quantum coupling layer to the second photovoltaic device 215 may be absorbed by the second photovoltaic device 215 to generate further electrons and holes. The charge-coupling layer 210 may couple electrons from the second photovoltaic device 215 to holes or fixed charges in the second layer 205b. Electrons from the device 215 may be transmitted to the load via serial or parallel connection to device 205.

In one embodiment, charge-coupling may be via direct tunneling. In another embodiment, charge-coupling may be via Fowler Nordheim (i.e., field emission) coupling. In another embodiment, charge-coupling may be via inductive coupling.

In one embodiment, the first layer 205a and the second layer 205b may be separate layers. In another embodiment, the first layer 205a and the second layer 205b may be intermixed layers.

In one embodiment, the first photovoltaic device 205 may include one or more layers in addition to the first and second layers 205a and 205b, respectively. In another embodiment, the first photovoltaic device 205 may include 1 or more, or 2 or more, or 3 or more, or 4 or more, or 5 or more, or 6 or more, or 7 or more, or 8 or more, or 9 or more, or 10 or more additional layers.

With continued reference to FIG. 2, one or more of the first layer 205a, second layer 205b and QCL 210 may be antireflection layers. In some cases, the PV cell 200 may include an anti-reflective layer above the first PV device 205. The anti-reflective layer may be configured to prevent or minimize light from being reflected out of the PV cell 200. The anti-reflective coating layer may be formed of a dielectric anti-reflecting coating (DARC) material. In another embodiment, the anti-reflective coating layer may be formed of a nitride, such as, for example, silicon rich silicon oxynitride. In another embodiment, the PV module may include a layer of reflective material below the second PV device 215. The layer of reflective material is configured to reflect light passing through the second PV device 215 back into the second PV device 215, the QCL 210 and the first PV device 205.

During activation, the materials of the first layer 205a and second layer 205b of the first PV device 205 may intermix or diffuse into one another to create an additional, mixed layer. The mixed layer may have an effective band gap between a band gap of the first layer 205a and a band gap of the second layer 205b. In another embodiment, the material of the first layer 205a may diffuse into the second layer 205b. In another embodiment, the material of the second layer 205b may diffuse into the first layer 205a.

The first layer 205a may have a thickness greater than one monolayer. For instance, the first layer 205a may have a thickness between about 100 nanometers (“nm”) and 10 micrometer (“μm”). In some situations, the first layer 205a may have a thickness greater than or equal to about 1 nm, or 2 nm, or 5 nm, or 10 nm, or 20 nm, or 50 nm, or 100 nm, or 200 nm, or 500 nm, or 1000 nm, or 2000 nm, or 5000 nm, or 10,000 nm. In other situations, the first layer 205a may have a thickness between about 1 nm and 1000 nm, or between about 5 nm and 500 nm, or between about 10 nm and 200 nm.

The second layer 205b may have a thickness greater than one monolayer. For instance, the second layer 205b may have a thickness between about 100 nm and 500 nm. In some situations, the second layer 205b may have a thickness greater than or equal to about 1 nm, or 2 nm, or 5 nm, or 10 nm, or 20 nm, or 50 nm, or 100 nm, or 200 nm, or 500 nm, or 1000 nm, or 2000 nm, or 5000 nm, or 10,000 nm. In another embodiment, the second layer 205b has a thickness between about 1 nm and 1000 nm, or between about 5 nm and 500 nm, or between about 10 nm and 200 nm.

The charge-coupling layer 210 may have a thickness greater than one monolayer. For instance, the charge-coupling layer 210 may have a thickness greater than or equal to about 1 nm, or 2 nm, or 5 nm, or 10 nm, or 20 nm, or 50 nm. The charge-coupling layer 210 may have a thickness between about 1 nm and 100 nm, or 1.5 nm and 50 nm, or 2 nm and 10 nm. For example, the charge-coupling layer 210 may have a thickness greater than 1 nm, or 2 nm, or 3 nm, or 4 nm, or 5 nm, or 6 nm, or 7 nm, or 8 nm, or 9 nm, or 10 nm, or 20 nm, or 30 nm, or 40 nm, or 50 nm, or 100 nm.

The second photovoltaic device 215 may have a thickness greater than 1 monolayer. The second PV device 215 may have a thickness greater than or equal to about 1 nm, or 2 nm, or 5 nm, or 10 nm, or 20 nm, or 50 nm, or 100 nm, or 200 nm, or 500 nm, or 1000 nm, or 2000 nm, or 5000 nm, or 10,000 nm, or 20 μm, or 100 μm, or 200 μm, or 500 μm.

In some cases, the second PV device 215 may have a thickness between about 10 nm and 100 μm. In other cases, the thickness of the PV device 215 may be greater than about Y multiplied by the number of Debye Lengths (D) multiplied by the number (N) of n-p or p-n junctions across an electric path of the second photovoltaic device 215, i.e., Y×D×N (‘x’ designates the multiplication operator), where ‘Y’ is a number greater than or equal to 0.In one embodiment, the second photovoltaic device 215 has a thickness greater than or equal to about 0.5×D×N, or greater than or equal to about 1×D×N, or greater than or equal to about 2×D×N, or greater than or equal to about 3×D×N, or greater than or equal to about 4×D×N, or greater than or equal to about 5×D×N, or greater than or equal to about 6×D×N, or greater than or equal to about 7×D×N, or greater than or equal to about 8×D×N, or greater than or equal to about 9×D×N, or greater than or equal to about 10×D×N, or greater than or equal to about 100×D×N, or greater than or equal to about 1000×D×N.

With continued reference to FIG. 2, the QCL 210 permits light to pass from the first PV device 205 to the second PV device 215. The QCL couples charge (e.g., electrons) in the second PV device 215 to charge (e.g., holes, positive charges) in the first PV device 205. In one embodiment, charge coupling may permit electrons in the second PV device 215 to quantum mechanically tunnel to the first PV device 205.

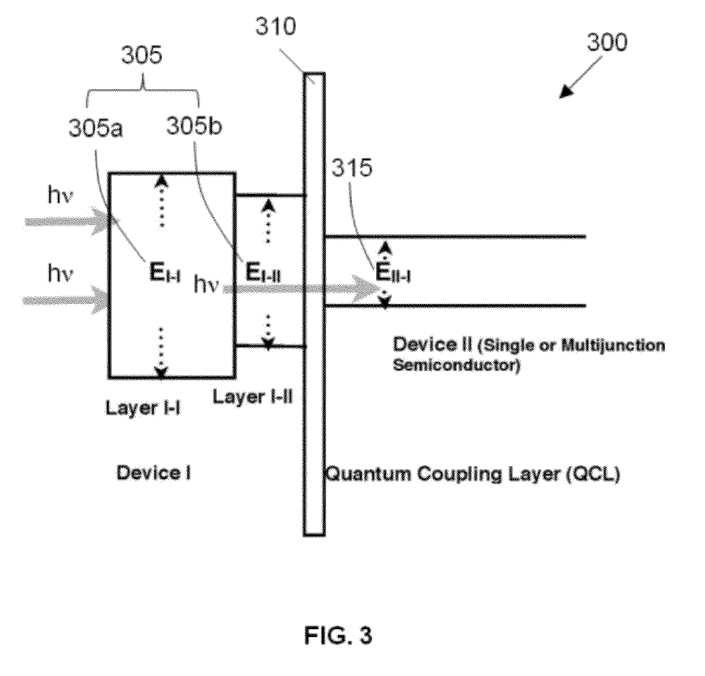

FIG. 3 is a schematic energy band diagram 300 of a photovoltaic cell having a first photovoltaic device (Device I) adjacent a charge-coupling layer, and a second photovoltaic device (Device II) adjacent the charge-coupling layer, in accordance with an embodiment of the invention. The first PV device includes a first layer (Layer I-I) and a second layer (Layer I-II) adjacent the first layer and the charge-coupling layer. The energy band diagram 300 may be for the cell 200 discussed in the context of FIG. 2. Static or dynamic band banding is not shown in FIG. 3.

With continued reference to FIG. 3, the first layer (Layer I-I) of the first photovoltaic device (Device I) is formed of a semiconductor material having a first band gap 305a (E_{I-I}), and the second layer (Layer I-II) of the first photovoltaic device is formed of a semiconductor material having a second band gap 305b (E_{I-II}), which may be an effective band gap (or excitation potential). The first band gap 305a is greater than the second band gap 305b. The charge-coupling layer may be formed of an insulating, semi-insulating and/or dielectric material having a band gap 310. The second photovoltaic device (Device II) is formed of a material having a third band gap 315 (E_{II-I}). The charge-coupling layer, as illustrated, is a quantum coupling layer (QCL). At an interface of the charge-coupling layer and the second layer, the device has effective band gap E_{I-I}≧E_{I-II}≧E_{II-I}. In some cases, the energy band gap configuration may be E_{I-I}>E_{I-II}>E_{II-I}. The band gap of the quantum coupling insulator is greater than E_{I-I}. The first layer and the second layer of Device I may be two separate layers and/or intermixed. The second photovoltaic device (Device II) may be a single or multijunction photovoltaic device. The band gap of the charge-coupling layer 310 is greater than the first band gap 305a, second band gap 305b and third band gap 315.

With continued reference to FIG. 3, light may propagate through the cell along the direction of the arrows indicated in the figure. At least a portion of light incident on the first photovoltaic device is transmitted through the first layer to the second layer. At least a portion of the light passing through the second layer is absorbed by the second layer to generate electrons in the second layer. Light that is not absorbed by the second layer may pass through the charge-coupling layer to the second photovoltaic device, which may absorb light to generate electrons.

The first band gap 305a may be greater than or equal to the second band gap 305b, and the second band gap 305b may be greater than or equal to the third band gap 315. The first band gap 305a may be greater than about 0 eV, or greater than or equal to about 0.1 eV, or 0.2 eV, or 0.5 eV, or 1 eV, or 2 eV, or 3 eV or 4 eV. In some situations, the first band gap 305a may be between about 2 eV and 4 eV. In some cases, the first band gap 305a may be between about 2 eV and 4 eV, or between about 2.5 eV and 3.5 eV. The second band gap (or excitation potential) 305b may be greater than about 0 eV, or greater than or equal to about 0.1 eV, or 0.2 eV, or 0.5 eV, or 1 eV, or 2 eV, or 3 eV. In some situations, the second band gap 305b may be greater than 1.1 eV, or between about 1.2 eV and 3 eV. In other situations, the second band gap 305b may be between about 1 eV and about 3 eV, or between about 1.2 eV and 2 eV. The third band gap 315 may be greater than about 0 eV, or greater than or equal to about 0.1 eV, or 0.2 eV, or 0.5 eV, or 1 eV, or 2 eV or 3 eV.

In some situations, the third band gap 315 may be between about 1.1 eV and 2 eV. The band gap 310 may be greater than about 0 eV, or greater than or equal to about 0.1 eV, or 0.2 eV, or 0.5 eV, or 1 eV, or 2 eV, or 5 eV, or 10 eV. In some situations, the band gap 310 may be between about 4 eV and 10 eV.

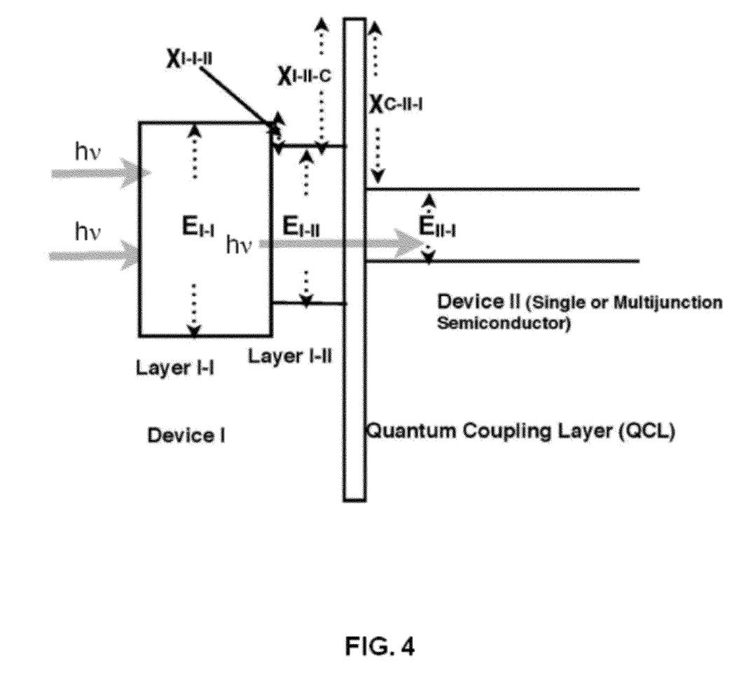

FIG. 4 is a schematic energy band diagram of a photovoltaic device having a first photovoltaic (“PV”) device (Device I), a charge-coupling layer adjacent Device I, and a second photovoltaic device (Device II) adjacent the charge-coupling layer, in accordance with an embodiment of the invention. FIG. 4 illustrates barrier heights and electron affinities (χ or “X”) for layers I-I and I-II of the first PV device (Device I), charge-coupling layer and the second PV device (Device II), χ_{C-II-I}≧χ_{I-II-C}≧χ_{I-I-II}. In some situations, the configuration of electron affinities may be χ_{C-II-I}>χ_{I-II-C}>χ_{I-I-II}, wherein χ_{C-II-} is the electron affinity at the interface of the quantum coupling layer (QCL) and Device II. The layers I-I and I-II could be two separate layers and/or intermixed with affinities χ_{C-II-I}≧χ_{I-II-C}≧χ_{I-I-II}. Static or dynamic band bending is not shown in the illustrated embodiment of FIG. 4. In one embodiment, χ_{I-I-II} may be greater than about 0 eV, or 0.1 eV, or 0.2 eV, or 0.3 eV, or 0.4 eV, or 0.5 eV, or 1 eV, or 2 eV, or 5 eV, or 10 eV. In another embodiment, ω_{I-II-C} may be greater than the maximum energy of electrons (eₘₐₓ) of electrons in Layer I-II of Device I. In another embodiment, χ_{C-II-I} may be greater than eₘₐₓ in Device II. The QCL may have a band gap that is greater than E_{I-I}, E_{I-II} and E_{II-I}.

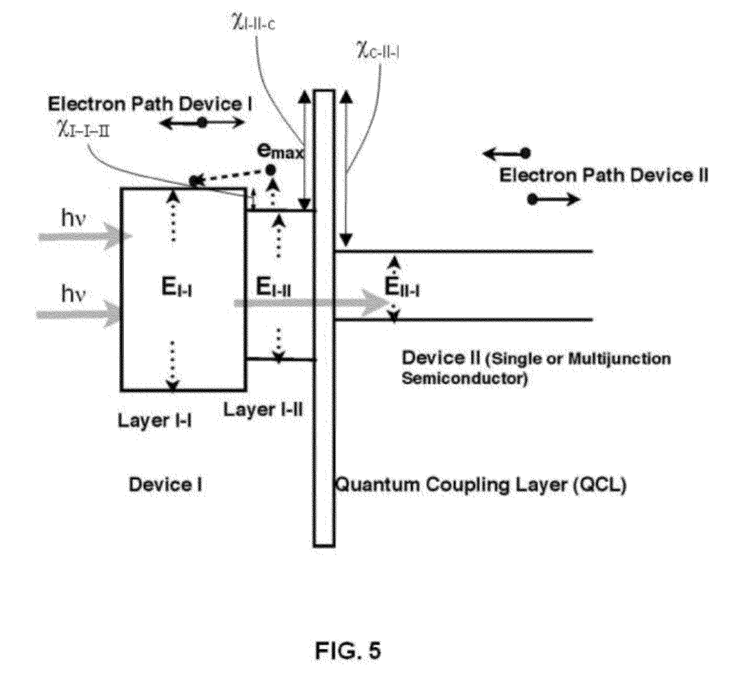

FIG. 5 is a schematic energy band diagram, illustrating the barrier heights and electron affinity of layers I-I, I-II, coupling layer and the device II, in accordance with an embodiment of the invention. Static or dynamic band banding has not been shown. The maximum energy of electrons in Device I or Layer I-II is designated by eₘₐₓ. In the illustrated energy band diagram, χ_{I-II-II}≦e_{maxI-II}≦χ_{I-II-C}≦χ_{C-II-I}, and e_{maxI-II} is equal to the maximum energy of the absorbed photons minus the band gap (or the excitation potential) of Layer I-II. In some cases, χ_{I-II-II}<e_{maxI-II}<χ_{I-II-C}<χ_{C-II-I}. With these barrier heights and the electron affinity specifications for layers I-I, I-II, the quantum coupling layer and the device II, high energy electrons are blocked from reaching Device II and they transport in the conduction band of the layer I-I, reduce high energy electrons generation and transfer to device II and thus reduce the thermalisation loss in device II.

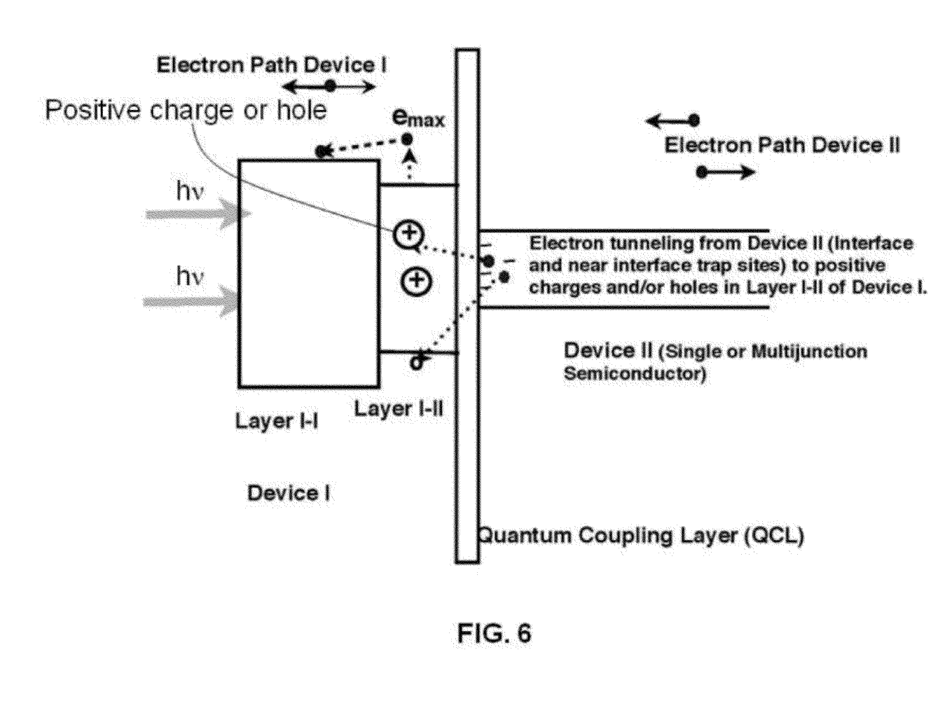

FIG. 6 is a schematic energy band diagram, illustrating the coupling of charges from Device II to Layer I-II of Device I, in accordance with an embodiment of the invention. Static or dynamic band banding has not been shown. Electrons and/or holes in Device II quantum mechanically couple to Layer I-II and quench the photon-generated charges in Layer I-II. This quantum mechanical coupling (or charge-coupling) is either in the direct tunneling mode and/or Fowler Nordheim tunneling mode. The electrons and/or holes absorbed by the interface states at or near the charge coupling-layer and Device-II interface also quantum mechanically couple to Layer I-II and therefore contribute toward power generation and reducing interface and near interface recombination losses in the Device II. In an example, by quenching positive charges in Layer I-II, recombination losses associated with electrons in Device I and Device II may be minimized.

In other embodiments, photovoltaic cells may include a first photovoltaic (“PV”) device adjacent a quantum coupling layer, and a second PV device adjacent the quantum coupling layer, the first photovoltaic device having an absorption layer. In one embodiment, the first PV device may include a transport layer, the transport layer formed of a material having an energy band gap greater than or equal to an energy band gap of the absorption layer. The absorption layer may be disposed between the quantum coupling layer and the transport layer.

In one embodiment, the absorption layer may include a single or multilayer of semiconductor (or semiconductor-containing) or semi-insulator thin film. In another embodiment, the absorption layer may include a single layer or multilayer of semiconductor (or semiconductor-containing) quantum wells. In another embodiment, the absorption layer may include a single layer or multilayer of semiconductor (or semiconductor-containing) quantum dots. The quantum dots may be disposed on a thin film semiconductor layer or quantum well layer. In another embodiment, the absorption layer may include a single layer or multilayer of nanostructures or nanowires. In another embodiment, the absorption layer may include a single layer or multilayer of semiconductor-containing nanostructures or nanowires.

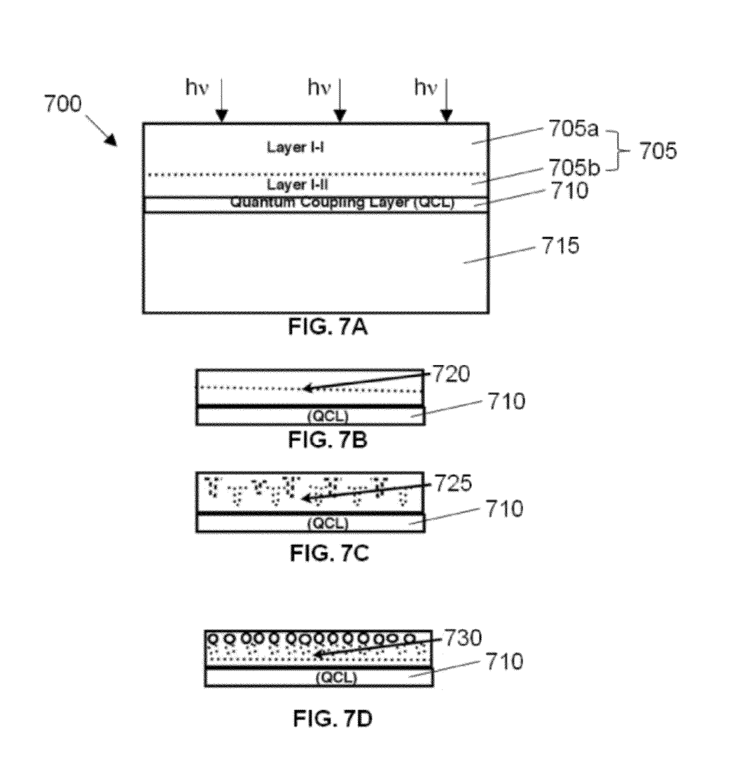

With reference to FIG. 7A, a photovoltaic cell 700 is provided having a first photovoltaic device (Device I) 705 adjacent a quantum coupling layer (QCL) 710, and a second photovoltaic device (Device II) 715 adjacent the QCL 710, in accordance with an embodiment of the invention. In embodiments, the first photovoltaic device 705 may include a light transmission layer 705a formed of a material for directing light to an absorption layer 705b, the absorption layer formed of a material for generating charge (e.g., electrons and holes) when exposed to light.

FIGS. 7B-7D show various configurations of the absorption layer 705B, in accordance with various embodiments of the invention. With reference to FIG. 7B, the absorption layer 705b may include a single layer or multiple layers (also “multilayer” herein) of a semiconductor material 720. In such a case, the cell 700 may have effective band gaps E_{I-I}≧E_{I-II}≧E_{II-I}, where E_{I-I} is the effective band gap of the light transmission layer 705a, E_{I-II} is the effective band gap of the absorption layer 705b, and E_{II-I} is the effective band gap of the semiconductor near the interface of the quantum coupling layer 710 and second photovoltaic device 715 (not shown). In some cases, the energy band gap configuration may be E_{I-I}>E_{I-II}>E_{II-I}. With reference to FIG. 7C, the absorption layer 705b may include a single layer or multiple layers of semiconductor quantum wells 725 having a band gap (E_{I-II}) that is greater than or equal to a band gap (E_{II-I}) of semiconductor material near the interface of the quantum coupling layer 710 and the second photovoltaic device 715 (not shown). In some situations, E_{I-II} may be greater than E_{II-I}. In one embodiment, quantum wells may be formed of a semiconductor layer sandwiched between the material of the transport layer and/or the material of the quantum (or charge) coupling layer. With reference to FIG. 7D, the absorption layer 705b may include a single or multiple layers of semiconductor quantum dots 730. In one embodiment, the quantum dots 730 may be disposed on single or multilayered quantum wells and/or semiconductor layers. The absorption layer may have a band gap (E_{I-II}) that is greater than or equal to a band gap (E_{II-I}) of semiconductor material near the interface of the quantum coupling layer 710 and second photovoltaic device 715 (not shown). In some situations, E_{I-II} may be greater than E_{II-I}. In another embodiment, the quantum dots 730 may be formed of semiconductor particles embedded in the material of the transport layer 705a and/or the material of the quantum coupling layer 710.

In one embodiment, the first PV device 705 includes a layer of quantum dot material. The quantum dots may be disposed in the absorption layer 705b. In another embodiment, the first PV device 705 includes a layer of quantum well material. The quantum wells may be disposed in the absorption layer 705b. Quantum dot and quantum well materials may include Group IV, IV-IV, III-V, II-VI , III-VI semiconductors.

In one embodiment, a cell is provided having a first photovoltaic (PV) device adjacent a quantum coupling layer (QCL), and a second PV device adjacent the QCL, the first PV device comprising dye (or dye-containing) material (“dye”). The dye may have an excitation potential greater than about 0 eV, or greater than or equal to about 0.1 eV, or 0.2 eV, or 0.5 eV, or 0.6 eV, or 1 eV, or 2 eV. In some situations, the dye may have an excitation potential greater than about 1.1 eV, or between about 1.2 eV and 3 eV. The dye emit light in the green or red portion of the visible spectrum.

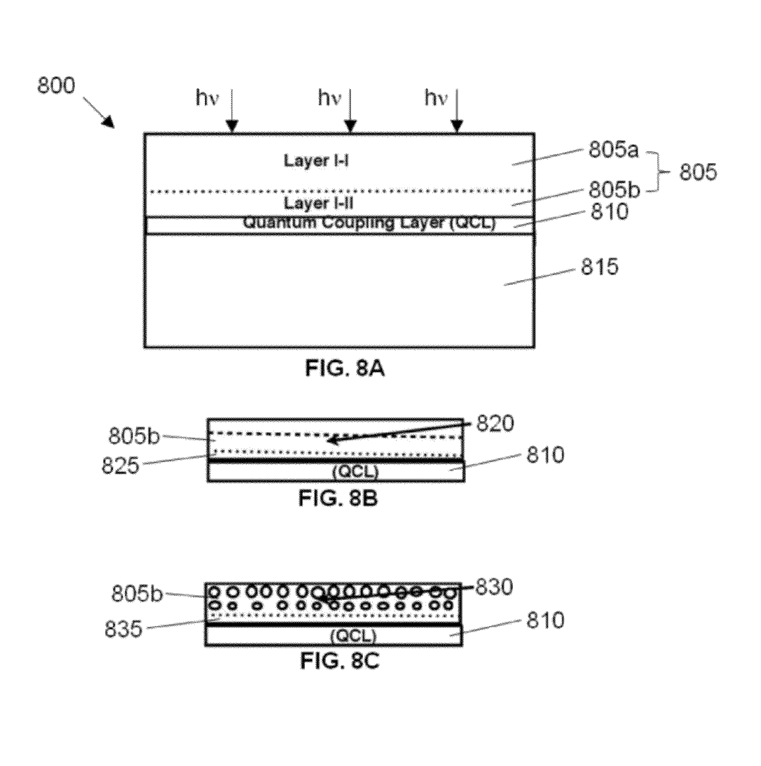

With reference to FIG. 8A, a photovoltaic cell 800 is provided having a first photovoltaic device (Device I) 805 adjacent a quantum coupling layer (QCL) 810, and a second photovoltaic device (Device II) 815 adjacent the QCL 810, in accordance with an embodiment of the invention. The first photovoltaic device 805 may include a light transmission layer 805a formed of a material for directing light to an absorption layer 805b, the absorption layer formed of a material for generating charge (e.g., electrons and holes) when exposed to light. In one embodiment, the absorption layer may include a dye (or dye-containing) material. The dye (or dye-containing) material may include photon-absorbing material. With reference to FIG. 8B, the absorption layer 805b may include single or multi-layered dyes. In one embodiment, the dyes may be formed directly on the coupling layer 810. In another embodiment, the dyes 820 may be formed on a semiconductor layer 825 on the coupling layer 810 or absorbed in the semiconductor layer 825. With reference to FIG. 8C, the absorption layer 805b may include single or multilayered quantum dots 830 having a dye (or dye-containing) material. In one embodiment, the quantum dots 830 may be formed directly on the coupling layer 810. In another embodiment, the quantum dots 830 may be formed on a semiconductor layer 835 on the coupling layer. In one embodiment, the quantum dots are dye-containing quantum dots. Such quantum dots may be formed of one or more dyes embedded in the transport layer 805a, the semiconductor layer 825 and/or the coupling layer 810, or the transport layer 805a and the coupling layer 810.

With reference to FIGS. 8A-8C, the absorption layer 805b may have an effective band gap (E_{I-II}), or ionizing potential, that is greater than or equal to an effective band gap (or ionizing potential) of the second PV device 815 and an effective band gap (E_{II-I}), or ionizing potential, at an interface of the QCL 810 and the second PV device 815. In some situations, E_{I-II} may be greater than E_{II-I}. This may permit a fraction of light incident on the module 800 to be absorbed by the absorption layer 805, thereby generating charge (e.g., electrons and holes), and a remaining fraction of the light incident on the cell 800 to be transmitted through the QCL 810 to the second PV device 815 to generate additional charge (e.g., electrons and holes).

In embodiments, a photovoltaic (“PV”) cell may include a plurality of PV devices separated by a quantum coupling layer (QCL). The photovoltaic devices and QCL may include one or more three-dimensional structures to increase the effective surface area of the PV cell, which may increase the effective area for absorption of light and the generation of charge (e.g., electrons and holes). One or more photovoltaic devices and QCL of the module may include V-shaped grooves (also “V-grooves” herein). One or more structures of the cell, including the PV devices and the QCL, may include nanostructures in the bulk, surfaces, or interfaces of the structures.

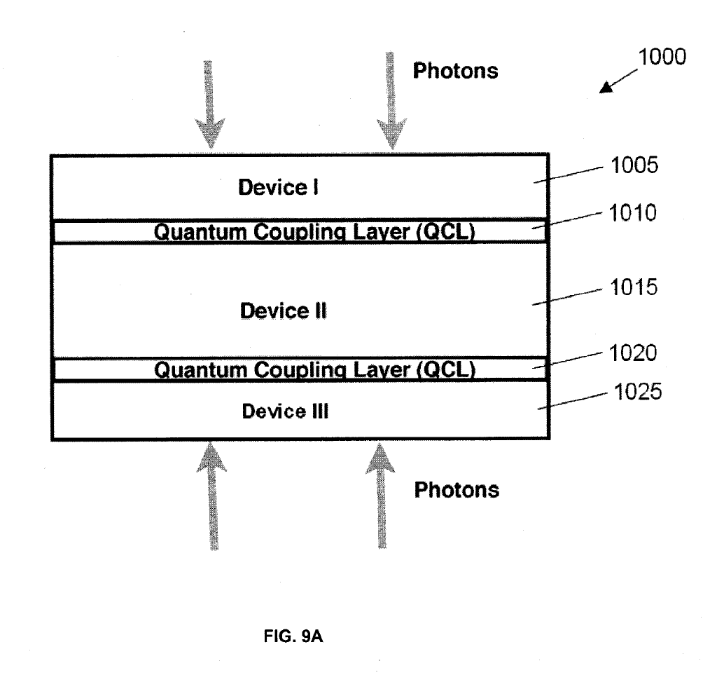

With reference to FIG. 9A, a photovoltaic cell 900 is shown, comprising a first PV device 905, QCL 910, and second PV device 915, in accordance with an embodiment of the invention. The first PV device 905, QCL 910 and second PV device 915 include three-dimensional structures. The three-dimensional structures may increase the effective surface area for the absorption of light and generation of charge (e.g., electrons and holes). The PV module 900 is configured to accept light (hν) in the first PV device 905.

With continued reference to FIG. 9A, the first PV device 905 includes a first layer (Layer I-I) 905a and second layer (Layer I-II) 905b. The first layer 905a includes a material for transmitting light to the second layer 905b. In one embodiment, the first layer 905a is formed of a transparent or semi-transparent material. The first layer 905a may be formed of a semi-transparent semiconductor (or semiconductor-containing) or semi-insulator material, or transparent semiconductor (or semiconductor-containing) or semi-insulator material. The second layer 905b includes material for absorbing photons to generate charge (e.g., electrons, holes). The second layer 905b may be formed of a semiconductor or semiconductor-containing material. In some embodiments, the properties (e.g., thickness, compositions) of the first layer 905a may be similar or identical to the properties of the first layer 205a of FIG. 2, and the properties of the second layer 905b may be similar or identical to the properties of the second layer 205b.

With continued reference to FIG. 9A, the second PV device 915 may include a first junction 920, a second junction 925, or both. Each of the first junction 920 and second junction 925 may be an n-p or p-n junction. The junctions 920 an 925 may be formed as planar or three-dimensional junctions, or a passivated emitter and rear cell (PERC), passivated emitter, rear locally diffused cell (PERL) or tandem junction cell.

The second photovoltaic device 915 may include a first layer 926, second layer 927, and third layer 928. In some cases, the first layer 926 may be formed of an n-type (i.e., doped n-type) semiconductor material, the second layer 927 is formed of a p-type (i.e., doped p-type) semiconductor material, and the third layer 928 is formed of an n-type semiconductor material. In such a case, the first junction 920 is an n-p junction (as defined from the top down) and the second junction 925 is a p-n junction. Alternatively, the first layer 926 may be formed of a p-type semiconductor material, the second layer 927 is formed of an n-type semiconductor material, and the third layer 928 is formed of a p-type semiconductor material. In such a case, the first junction 920 is a p-n junction and the second junction 925 is an n-p junction.

With continued reference to FIG. 9A, in one embodiment, the PV cell 900 may include an anti-reflective layer above the first PV device 905. The anti-reflective layer is configured to prevent or minimize light from being reflected out of the PV cell 900. The anti-reflective coating layer may be formed of a dielectric anti-reflecting coating (DARC) material. In another embodiment, the anti-reflective coating layer may be formed of a nitride, such as, for example, silicon rich silicon oxynitride. In another embodiment, the PV cell may include a layer of reflective material below the second PV device 915. The layer of reflective material may be configured to reflect light passing through the second PV device 915 back into the second PV device 915, the QCL 910 and the first PV device 905. The layer of reflective material may be formed of a silicon oxide (i.e., SiOₓ, wherein ‘x’ is a number greater than zero), silicon oxynitride, silicon nitride, or titanium oxide (i.e., TiOₓ, wherein ‘x’ is a number greater than zero).

The first layer 905a may have a thickness greater than one monolayer. The first layer 905a may have a thickness between about 100 nanometers (“nm”) and 10 micrometer (“μm”). In some situations, the first layer 905a may have a thickness greater than or equal to about 1 nm, or 2 nm, or 5 nm, or 10 nm, or 20 nm, or 50 nm, or 100 nm, or 200 nm, or 500 nm, or 1000 nm, or 2000 nm, or 5000 nm, or 10,000 nm. In other situations, the first layer 905a may have a thickness between about 1 nm and 1000 nm, or between about 5 nm and 500 nm, or between about 10 nm and 200 nm.

The second layer 905b may have a thickness greater than one monolayer. The second layer 905b may have a thickness between about 100 nm and 500 nm. In some situations, the second layer 905b may have a thickness greater than or equal to about 1 nm, or 2 nm, or 5 nm, or 10 nm, or 20 nm, or 50 nm, or 100 nm, or 200 nm, or 500 nm, or 1000 nm, or 2000 nm, or 5000 nm, or 10,000 nm. In some cases, the second layer 905b may have a thickness between about 1 nm and 1000 nm, or between about 5 nm and 500 nm, or between about 10 nm and 200 nm.

The QCL 910 may have a thickness greater than one monolayer. In some cases, the QCL 910 may have a thickness greater than or equal to about 1 nm, or 2 nm, or 3 nm, or 4 nm, or 5 nm, or 6 nm, or 7 nm, or 8 nm, or 9 nm, or 10 nm, or 20 nm, or 30 nm, or 40 nm, or 50 nm, or 100 nm. The thickness of the QCL 910 may be selected to provide a band gap as desired. In some situations, the QCL 910 may have a thickness between about 1 nm and 100 nm, or 1.5 nm and 50 nm, or 2 nm and 10 nm.

The second photovoltaic device 915 may have a thickness greater than 1 monolayer. The second PV device 915 may have a thickness greater than or equal to about 1 nm, or 2 nm, or 5 nm, or 10 nm, or 20 nm, or 50 nm, or 100 nm, or 200 nm, or 500 nm, or 1000 nm, or 2000 nm, or 5000 nm, or 10,000 nm, or 20 μm, or 100 μm or 200 μm, or 500 μm.

In some cases, the second PV device 915 may have a thickness between about 10 m and 100 μm. In other cases, the second PV device 915 may have a thickness that is greater than about Y multiplied by the number of Debye Lengths (D) multiplied by the number (N) of n-p or p-n junctions across an electric path of the second photovoltaic device 915, i.e., Y×D×N (‘x’ designates the multiplication operator), where ‘Y’ is a number greater than or equal to 0. In one embodiment, the second photovoltaic device 915 has a thickness greater than or equal to about 0.5×D×N, or greater than or equal to about 1×D×N, or greater than or equal to about 2×D×N, or greater than or equal to about 3×D×N, or greater than or equal to about 4×D×N, or greater than or equal to about 5×D×N, or greater than or equal to about 6×D×N, or greater than or equal to about 7×D×N, or greater than or equal to about 8×D×N, or greater than or equal to about 9×D×N, or greater than or equal to about 10×D×N, or greater than or equal to about 100×D×N, or greater than or equal to about 1000×D×N.

The PV module 900 of FIG. 9A may be an illustration of the planar concept of FIG. 2 translated to a three-dimensional (“3D”) structure. The 3D structure may increase the effective area for light absorption and electron generation by the first PV device 905 and the second PV device 915. That is, the 3D structure may increase the effective area for light absorption, which may provide for improved solar cell efficiency.

With reference to FIG. 9B, a cross-sectional side view of a 3D structure comprising a V-groove is shown, in accordance with an embodiment of the invention. Each groove 929 may have a width (“W”) and depth (“d”). The width-to-depth ratio, W/d, may be adjusted to optimize photon absorption while keeping the electric field on the QCL 910 less than the breakdown strength of the QCL 910. In some cases, W may be between about 0.1 μm and 100 μm. In other cases, W may be greater than or equal to about 1 nm, or 10 nm, or 100 nm, or 1000 nm, or 2 μm, or 5 μm or 10 μm, or 100 μm, or 500 μm, and d may be between about 0.1 μm and 100 μm. In other cases, W and d may be greater than or equal to about 1 nm, or 10 nm, or 100 nm, or 1000 nm, or 2 μm, or 5 μm, or 10 μm, or 100 μm, or 500 μm. In some situations, W may be greater than or equal to about 1 monolayer (ML) In other situations, W and d may be greater than or equal to about 1 ML.

With reference to FIG. 9C, a cross-sectional side view of a 3D structure having lines 930 is shown, in accordance with an embodiment of the invention. The lines are defined by protrusions 931 having a width (“W”) and height or depth (“d”), in accordance with an embodiment of the invention. The width of each line may be shorter than a length (along an axis orthogonal to the plane of the page) of the line. The width-to-depth ratio, W/d, may be adjusted to optimize photon absorption while keeping the electric field on the QCL 910 less than the breakdown strength of the QCL 910. In some cases, W may be between about 0.1 μm and 100 μm. In other cases, W may be greater than or equal to about 1 nm, or 10 nm, or 100 nm, or 1000 nm, or 2 μm, or 5 μm, or 10 μm, or 100 μm, or 500 μm, and d may be between about 0.1 μm and 100 μm. In other cases, W and d may be greater than or equal to about 1 nm, or 10 nm, or 100 nm, or 1000 nm, or 2 μm, or 5 μm, or 10 μm, or 100 μm, or 500 μm. In some situations, W may be greater than or equal to about 1 monolayer (ML) In other situations, W and d may be greater than or equal to about 1 ML. The W/d ratio may be optimized for maximum photon absorption. The depth may be optimized to keep the electric field on the QCL 910 less than the breakdown strength (or voltage) of the QCL 910. In some embodiments, the 3D structure may include vias. In other embodiments, the 3D structure may include lines and vias.

With reference to FIG. 9D, a cross-sectional side view of a 3D structure comprising a plurality of cylindrical or elliptical structures 932 is shown, in accordance with an embodiment of the invention. The structure may include individual structures with diameter (“d”) and height (“H”), and the individual structures 932 may be spaced by spacing (“W”). In one embodiment, the structures 932 may have a length (along an axis orthogonal to the plane of the page) that is the same or substantially similar to the diameter of the structures 932. In one embodiment, the structures 932 are rods or rod-shaped structures. In another embodiment, the structures 932 are cylindrical rods. In another embodiment, the structures 932 are elliptical rods having a generally elliptical cross-section. In another embodiment, the structures 932 are box-like or rectangular in shape (or cross-section). The diameter, height and spacing may be optimized for maximum photon absorption. The height may be optimized to keep the electric field on the coupling layer less than the breakdown strength (or voltage) of the coupling insulator. The diameter may be between about 0.1 μm and 100 μm; the width may be between about 0.1 μm and 100 μm; and the height may be between about 0.1 μm and 100 μm. Alternatively, the diameter may be greater than or equal to about 1 nm, or 10 nm, or 100 nm, or 1000 nm, or 2 μm, or 5 μm or 10 μm, or 100 μm, or 500 μm; the width may be greater than or equal to about 1 nm, or 10 nm, or 100 nm, or 1000 nm, or 2 μm, or 5 μm, or 10 μm, or 100 μm, or 500 μm; and the height may be greater than or equal to about 1 nm, or 10 nm, or 100 nm, or 1000 nm, or 2 μm, or 5 μm, or 10 μm, or 100 μm, or 500 μm. As another alternative, the diameter may be greater than or equal to 1 ML, the width may be greater than or equal to 1 ML; and the height may be greater than or equal to 1 ML. The structures of FIG. 9D may be formed by various methods, such as methods described in U.S. Pat. No. 7,560,390 to Sant et al. (“MULTIPLE SPACER STEPS FOR PITCH MULTIPLICATION”), which is entirely incorporated herein by reference. The absorption layer (205b, 705b, 805b, 905b, 1025b, 1105b) may have one or more charge coupling layers with thicknesses and specifications similar to the layers 110, 210, 310, 410, 510, 610, 710, 810, 910, 1020 1110.

With reference to FIG. 9E, a 3D structure comprising a random rough surface is shown, in accordance with an embodiment of the invention. The random rough surface may include a corrugated surface. The corrugated surface may include features, such as pits and troughs, formed of self-assembled structures or porous materials. In one embodiment, such features may provide for enhanced photon absorption and to keeping the electric field on the QCL 910 less than the breakdown strength (or voltage) of the QCL 910.

In an embodiment, 3D structures may be formed in or on one or more layers of the module 900 via etching. For example, the structures of FIG. 9D may be formed by etching (e.g., anisotropic etching) with the aid of a mask. In another embodiment, 3D structures may be formed in or on one or more layers of the module 900 by deposition, such as chemical vapor deposition (CVD), atomic layer deposition (ALD), physical layer deposition, molecular beam epitaxy (MBE), digital CVD, plasma-enhanced CVD, plasma-enhanced ALD, or selective growth, such as, e.g., epitaxy, thermal oxidation or anodic oxidation.

Photovoltaic devices provided herein may be for use with front or back lighted modules, or modules in which photovoltaic cells receive light from opposing sides or all sides of photovoltaic modules. For example, a front and back side PV module may receive light from a front side and back side of the PV module. As another example, a PV module may be configured to receive light from opposing sides of the PV module (and PV cells therein).

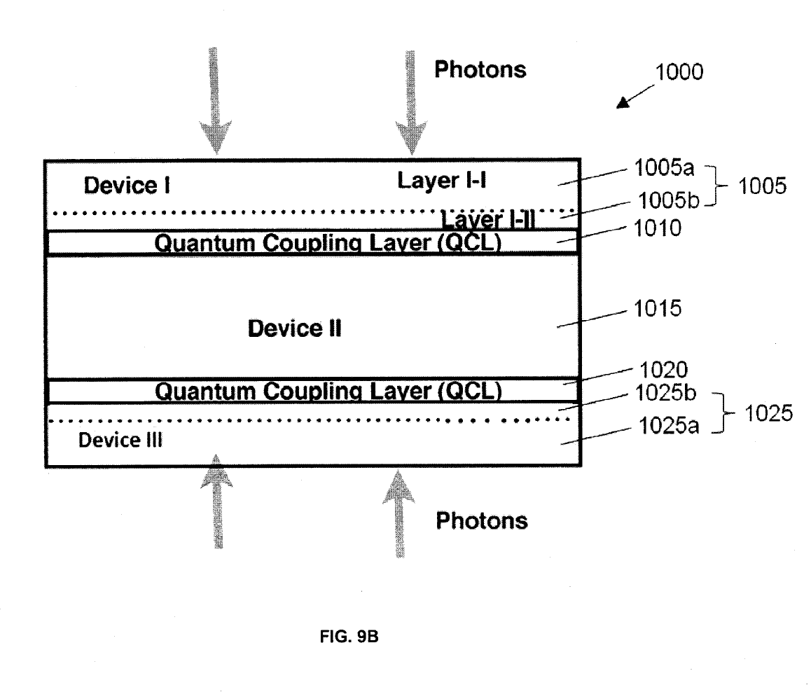

FIG. 10A shows a solar cell for receiving light from a front and back side of the solar cell modules, in accordance with an embodiment of the invention. With reference to FIG. 10A, a PV cell 1000 may include a first photovoltaic device (“Device I”) 1005, a first quantum coupling layer (QCL) (or charge-coupling layer) 1010 adjacent Device I 1005, a second photovoltaic device (“Device II”) 1015 adjacent the first QCL 1010, a second QCL (or charge-coupling layer) 1020 adjacent Device II 1015, and a third photovoltaic device 1025 adjacent the second QCL 1020. Quantum coupling layers 1010 and 1020 are for coupling charge between Device I 1005 and Device III 1025 to Device II 1015. In some cases, Device I 1005 and Device III 1025 may be the same photovoltaic device (i.e., Device I and Device III may have the same material properties, including energy band gaps). Alternatively, Device I 1005 and Device III 1025 may be different photovoltaic devices. In such a case, Device I and Device III may have different material properties.

In some cases, the first QCL 1010 and second QCL 1020 may be the same QCL and having similar or identical material properties. In other cases, the first QCL 1010 and second QCL 1020 may be different QCLs and thus having different material properties.

In the illustrated embodiment of FIG. 10A, the PV cell 1000 may be configured to accept photons from opposing sides of the cell 1000. In such a case, photons enter the cell 1000 through one or both of Device I 1005 and Device III 1025 and generate charge in Device I 1005 and Device III 1025. Each of the Device I-first QCL-Device II and Device III-second QCL-Device II may function as described above (see, e.g., FIG. 1).

With reference to FIG. 10B, in an alternative embodiment, each of the first photovoltaic device 1005 and third photovoltaic device 1025 may of the PV cell 1000 may include a transport layer (Layer I-I) and an absorption layer (Layer I-II). That is, the first photovoltaic device 1005 and third photovoltaic device 1025 may have the same transport and absorption layers. Alternatively, the first photovoltaic device 1005 and third photovoltaic device 1025 may have different transport and absorption layers. That is, the third photovoltaic device 1025 may include a transport layer (Layer III-I) that is different from Layer I-I and an absorption layer (Layer that is different from Layer I-II.

Device I 1005 may include a transport layer 1005a and an absorption layer 1005b, and Device III 1025 may include a transport layer 1025a and absorption layer 1025b. The transport and absorption layers may be similar, if not identical to other transport and absorption layers described herein.

The transport layers 1005a and 1025a and absorption layers 1005b and 1025b may be separate layers or intermixed layers (e.g., transport layer 1005a may be intermixed with absorption layer 1005b). Device I and Device III may have electrical properties similar, or identical to the device 105 of FIG. 1. Alternatively, layers 1005a and 1025a may be similar, or identical to layer 205a of FIG. 2, layer 705a of FIG. 7A or layers 805a of FIG. 8A; and layers 1005b and 1025b may be similar, or identical to layer 205b of FIG. 2, layer 705b of FIG. 7A, or layer 805b of FIG. 8A. QCLs 1010 and 1020 may be similar, or identical to QCL 110 of FIG. 1, QCL 210 of FIG. 2, QCL 710 of FIG. 7A, or QCL 810 of FIG. 8A. The cell 1000 may have one or more quantum coupling layers. In some cases, the cell 1000 may have multiple quantum coupling layers.

One or more sides of the cell 1000 may have 3D structures. For example, all sides, three sides or two sides of the cell 1000 may have 3D structures. In some situations, the indivdidual devices and layers of cell 1000 may be similar, or identical to those described below in the context of FIG. 9. For example, layers 1005a and 1025a may be similar, or identical to layer 905a of FIG. 9; layers 1005b and 1025b may be similar, or identical to layer 905b; QCL 1010 and QCL 1020 may be similar, or identical to QCL 910; and Device II 101 may be similar, or identical to the second PV device 915. The cell 1000 may have one or more quantum coupling layers. In some cases, the cell 1000 may have multiple quantum coupling layers.

With reference to FIGS. 10A and 10B, light enters the cell 1000 from opposing sides of the device, such as a front side and back side or left side and right side. Light may generate electrons and hold in the first photovoltaic devices 1005.Holes generated in the first photovoltaic devices 1005 may be quantum mechanically quenched by electrons from the second photovoltaic device 1010 adjacent the quantum coupling layer 1015. In some situations, any light unabsorbed by the first photovoltaic devices 1005 may pass through the quantum coupling layer 1015 and be absorbed by the second photovoltaic device 1010, in which case electrons and holes may be generated in the second photovoltaic device 1010.

One or more of the layers 1005a, 1005b, 1010, 1020, 1025a and 1025b may also act as antireflection reflection layers, which may improve the efficiency of the cell 1000. One or more additional antireflection (e.g., DARC) coating layers may be provided on one or both sides of the cell 1000, such as, for example, over layer 1005a and below layer 1025a such that light first passes through the additional antireflection coating layers before entering the cell 1000.

In some cases, the cell 1000 may be formed by first forming QCLs 1010 and 1020 around the Device II 1015, and subsequently forming Device I 1005 and Device III 1025—either simultaneously, Device III 1025 after Device I 1005, or Device I 1005 after Device III 1025—over the QCLs 1010 and 1020.

The cell 1000 may include an electrode at front and back surfaces of the cell 1000. The front and back electrodes may be in electrical communication with a front surface and back surface, respectively, of the cell 1000. In some cases, the cell 1000 may include an electrically conductive, metal or metal-containing, or heavily doped semiconducting electrode in the second photovoltaic device 1015 and in electrical communication with the first photovoltaic device 1005.

The photovoltaic devices and the charge coupling layers in the charge coupled cells (FIGS. 10A and 10B) may be electrically floating or connected to one another in serial or parallel mode. In some cases, photovoltaic cells, such as the cells of FIGS. 10A and 10B, may be electrically coupled to one another in a parallel or serial configuration to form photovoltaic modules. This may provide for a desired (or predetermined) voltage output and/or capacity of the modules.

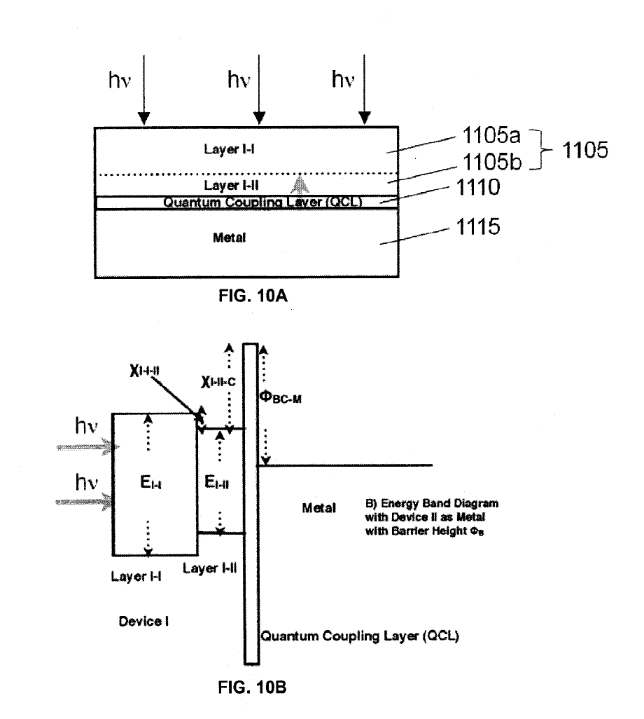

In an alternative embodiment, a photovoltaic cell may include a photovoltaic device adjacent a quantum coupling layer (“QCL”), and an electrically conducting layer adjacent the QCL. In some cases, the electrically conducting layer may include one or more metal layers. With reference to FIG. 11a, a photovoltaic cell 1100 may comprise a photovoltaic (“PV”) device 1105, a QCL 1110, and a electrically conducting layer 1115, in accordance with an embodiment of the invention. The electrically conducting layer 1115 may include one or more metals. In one embodiment, the electrically conducting layer 1115 includes a metal alloy. In another embodiment, the electrically conducting layer 1115 may include one or more metals, such as one or more of aluminum, titanium, tantalum, ruthenium, zirconium, vanadium, chromium and tungsten. In another embodiment, the electrically conducting layer 1115 may include a metal oxide, such as aluminum oxide, a conducting ceramic or conducting metal oxide (e.g., indium tin oxide, zinc oxide), or a conducting polymer. In another embodiment, Device II may be made of heavily doped semiconductors (e.g., n+, p+ silicon), conducting metal oxides and/or conducting polymers.

With continued reference to FIG. 11A, the first PV device 1105 of the PV cell 1000 includes a transport layer (Layer I-I) 1105a and an absorption layer (Layer I-II) 1105b. The transport layer 1105a is configured to transmit photons to the absorption layer 1105b. In one embodiment, the transport layer 1105a will not generate charge (e.g., electrons and holes) upon exposure to light. The absorption layer is configured to generate charge upon exposure to light. In one embodiment, the transport layer 1105a may generate less charge than the absorption layer 1105b.

With continued reference to FIG. 11A, the transport layer 1105a may be formed of a semiconductor (n-type, p-type or intrinsic) or semi-insulator material. In one embodiment, the transport layer 1105a is formed of an oxide of titanium or an oxide of a titanium alloy, such as TiOₓ, wherein ‘x’ is a number between 1 and 2, or between 1.5 and 2. In another embodiment, the transport layer 1105a may be formed of a transparent or semi-transparent oxide, such as a transparent or semi-transparent metal oxide. The absorption layer 1105b is a photon absorbing layer. The absorption layer 1105b may be formed of one or more dyes, quantum dots or quantum wells, quantum dot-containing dyes, a semiconductor material. The semiconductor material may include an n-p or p-n junction. In another embodiment, the absorption layer 1105b may be formed of one or more quantum wells. The absorption layer may be formed on the QCL 1110, or on a semiconductor layer (not shown) formed on the QCL 1110. Alternatively, the absorption layer 1105b may include one or more dyes formed in a semiconductor, semi-insulating or insulating material.

The absorption layer 1105b may include multi-layer dyes to absorb photons having energies greater than 0 eV, or greater than about 0.6 eV. Any unabsorbed photons may be reflected by the electrically conducting (e.g., metal) layer 1115. Reflected photons may then be absorbed by the absorption layer 1105b to contribute to the active current/power of the PV cell 1100. The electrically conducting layer 1115 may also be formed in a 3D configuration (see FIG. 9) to increase photon absorption and increase the active power of the PV module 1000.

During use, photons may be transmitted and absorbed by the photovoltaic device I and then transmitted through the quantum coupling insulator to device II. Device I may be formed of two layers, layers I-I and layer I-II. Layer I-I may be a semiconductor with band gap E_{I-I}. Layer I-II may be a layer of effective band gap (or excitation potential) E_{I-II}. A quantum coupling layer may separate device I from device II. At an interface between the coupling layer and device II, device II may have effective band gaps E_{I-I}≧E_{I-II}≧E_{II-I}. The band gap of the quantum coupling insulator may be greater than E_{I-I}. In some situations the band gap of the quantum coupling insulator may be greater than or equal to E_{I-I}.

The absorption layer 1105b may have one or more charge coupling layers with specifications similar to the layers 110, 210, 310, 410, 510, 610, 710, 810, 910, 1010, 1020 and/or 1110. In some cases, device II may be an electrically conductive (e.g., metal) layer, and device I, device II, device III and the charge coupling layers may be 3-dimensional. The absorption layer in a the one dimensional or 3-dimensional cell may have one or more charge coupling layers with specifications similar to the layers 110, 210, 310, 410, 510, 610, 710, 810, 910, 1010, 1020 and/or 1110.

Photons may strike layer I-I and transmit (or pass) through layer I-I to layer I-II, where high energy photons are absorbed to generate electrons and holes (or positive charges). Unabsorbed photons may be transmitted through the coupling layer to device II, where they are absorbed to generate electrons and holes. The quantum coupling layer (via tunneling through the insulator) couples electrons from device II to holes (or fixed charges) in layer I-II.

Photovoltaic solar cells provided herein, such as any of the one-dimensional (e.g., FIG. 2) or three-dimensional (FIG. 9A) cells, may include anti-reflective coating layers. For example, a PV cell having, from top to bottom, a first PV device, QCL and second PV device may include an anti-reflective coating layer over the first PV device, between the first PV device and QCL, between the QCL and the second PV device, or a combination of such configurations. As another example, a PV cell having, from top to bottom, a PV device, QCL and metal layer may include an anti-reflective coating layer between the PV device and the QCL, between the QCL and metal layer, or both. In some cases, an anti-reflective coating may include dielectric anti-reflecting coating material. In some cases, device II of a front and back-lighted cell may include an electrically conductive material

Device I, device II, device III and a QCL may be electrically connected to one another in serial or parallel mode. A plurality of PV cells, such as any PV cell provided herein, may be electrically coupled to one another to form PV modules. For example, a plurality of PV cells may be connected in series or parallel to form PV modules. Series or parallel connectivity may provide for a desired power output or capacity. For example, parallel connectivity may provide for a desired energy density. As another example, series connectivity may provide for a desired potential output.

### Methods for Forming Photovoltaic Solar Cell Modules and Devices

In another aspect of the invention, methods for forming a photovoltaic (“PV”) solar cell are provided, the solar cell including a first photovoltaic device, a charge-coupling layer adjacent the first photovoltaic device, and a second photovoltaic device adjacent the charge-coupling layer. The methods may be used to form any of the PV cells described herein, such as any of the PV cells of FIGS. 1-11.

Methods for forming a photovoltaic cells may include forming a first photovoltaic device, forming a charge-coupling layer on (or adjacent) the first photovoltaic device, and forming a second photovoltaic device on the charge-coupling layer. The first photovoltaic device may be a single junction photovoltaic device.

The first photovoltaic and second photovoltaic devices include one or more semiconductors or semi-insulators (e.g., electrical insulators that may carry an electrical current). The first photovoltaic and second photovoltaic devices may include a Group IV material having one or more of carbon, silicon and germanium, or a Group III-V semiconductor having material selected from aluminum, gallium, indium, nitrogen, phosphorous, arsenic, such as, for example, aluminum phosphide, aluminum arsenide, gallium arsenide, or gallium nitride.

The second PV device includes a transport layer and an absorption layer. The transport layer is configured to direct photons to the absorption layer. The absorption layer is configured to generate charge (e.g., electrons, holes) upon interaction with photons.

The first PV device may have a thickness greater than 1, or 2, or 3 Debye lengths (or Debye radius) times the number of n-p and/or p-n junctions across the electric path of the photovoltaic device (see above). In some cases, the first PV device may have a thickness greater than or equal to about 1 monolayer (ML), or 2 ML, or 3 ML, or 4 ML, or 5 ML, or 6 ML, or 7 ML, or 8 ML, or 9 ML, or 10 ML, or 20 ML, or 30 ML, or 40 ML, or 50 ML, or 100 ML, or 200 ML, or 300 ML, or 400 ML, or 500 ML, or 1000 ML. The first PV device may be formed by providing a substrate and forming a layer of a semiconductor-containing material on the substrate. The substrate may be a metal-containing layer, such as a metal electrode, or a semiconductor-containing layer, such as a quartz or silica substrate. In some cases, a layer of reflective material is formed on the substrate prior to forming the first PV device. The first PV device may be formed on a substrate or electrode via deposition, such as, e.g., CVD, ALD, plasma-enhanced CVD, plasma-enhanced ALD, or selective growth, such as, e.g., epitaxy (e.g., MBE), thermal oxidation or anodic oxidation. Deposition may be conducted with the aid of a vapor phase chemical having a desired species, such as, e.g., SiH₄ for a PV device having silicon. In another embodiment, the first PV device is formed of a silicon substrate. The silicon substrate may be intrinsic or doped p-type or n-type. The PV device may have a concentration of p-type or n-type dopants less than the degeneracy of the PV device. If an intrinsic silicon substrate is used, the silicon substrate may be subsequently doped with an n-type or p-type chemical dopant (“dopant”) via, for example, diffusion or ion implantation. Diffusion or ion implantation may be combined with thermal annealing to provide a desired dopant concentration profile. For a single junction photovoltaic device, the silicon substrate may have a thickness greater than about 3 Debye lengths. The photovoltaic device may have a thickness greater than about 1 monolayer. In some cases, the PV device may have a thickness between about 1 nm and 200 μm.

If an n-p junction is desired, a semiconductor substrate doped n-type may be doped with a p-type dopant. In another embodiment if a p-n junction is desired, a semiconductor substrate doped p-type may be doped with an n-type dopant. N-type doping may be achieved with the aid of nitrogen (N), phosphorous (P) or arsenic (As). In another embodiment, p-type doing is achieved with the aid of boron (B) or aluminum (Al). For Group III-V semiconductors, n-type doping may be achieved with the aid of selenium, tellurium, silicon, or germanium, and p-type doping may be achieved with the aid of beryllium, zinc, cadmium, silicon, or germanium. In some situations, n-type doping may be achieved with the aid of chemicals or materials capable of depositing n-type dopants on a semiconductor, and p-type doping may be achieved with the aid of chemicals or materials capable of depositing p-type dopants on a semiconductor.

Next, the silicon substrate may be etched to form a desired planar or 3D structure. In one embodiment, the silicon substrate may etched to form a V-groove. In another embodiment, a single crystal silicon substrate, such as <100> silicon (or Si(100)), is etched to form a V-groove. Etching may be accomplished with the aid of a mask to form a desired groove pattern coupled with an isotropic or anisotropic etch. In one embodiment, etching may be combined with thermal annealing, such as a temperature ramp to a predetermined temperature at a predetermined ramp rate.

Alternatively, if the semiconductor substrate is etched prior to forming an n-p or p-n junction, following etching, an n-p or p-n junction may be formed by diffusion or ion implantation. Diffusion or ion implantation may be coupled with thermal annealing.

Next, the charge-coupling (or “quantum-coupling”) layer is provided. In one embodiment, the charge-coupling layer is provided by forming a layer of an oxide on the first photovoltaic device on the first photovoltaic device. In another embodiment, a charge-coupling layer having a semi-insulating, insulating or dielectric material may be formed by depositing or growing a thermal oxide or oxynitride on the first photovoltaic device. The layer of oxide may be formed by oxidizing a top surface of the first photovoltaic device with the aid of an oxidizing chemical or an oxidizing material, including an organic or inorganic oxidizing material. In one embodiment, oxidizing chemicals may be selected from neutral and plasma-excited species of O₂, O₃, NO₂, H₂O, and/or H₂O₂.

The insulating layer with the charge-coupling layer may be formed by one or more heating and cooling cycles (also “heat cycles” herein). Such heat cycle for insulator growth may be sufficient to activate dopants for forming electrically active junctions. In another embodiment, prior to forming the insulating layer, dopants may be activated via a heating and cooling cycle, which may provide a desired dopant depth-concentration profile in the first photovoltaic device.

The insulator may have a thickness that is selected based on the tunneling mode. Alternatively, the insulator may have a thickness that depends on whether charge-coupling is achieved with the aid of quantum mechanical tunneling (also “direct tunneling” herein) or field emission (also “Fowler Nordheim tunneling” herein). In some cases, the charge-coupling layer (or quantum coupling layer) may have a thickness greater than about one monolayer. In other cases, the charge-coupling layer may have a thickness greater than about 1 nanometer (“nm”), or 2 nm, or 3 nm, or 4 nm, or 5 nm, or 6 nm, or 7 nm, or 8 nm, or 9 nm, or 10 nm, or 20 nm, or 30 nm, or 40 nm, or 50 nm, or 100 nm. In some implementations, the charge-coupling layer may have a thickness between about 1 nm and 100 nm, or 1.5 nm and 50 nm, or 2 nm and 10 nm.

Next, following formation of the charge-coupling layer over the first photovoltaic device, the second photovoltaic device is formed on the charge-coupling layer. In one embodiment, the second photovoltaic device may be formed by any deposition technique known in the art, such as, e.g., CVD, ALD, plasma-enhanced CVD, or plasma-enhanced ALD. Deposition may be conducted with the aid of a vapor phase chemical having a desired species, such as, e.g., SiH₄ for a PV device having silicon.

The second PV device may include a transport layer and an absorption layer. Following formation of the charge-coupling layer, the absorption layer is provided. In one embodiment, the absorption layer may be provided by a deposition technique, such as, for example, CVD, ALD, plasma-enhanced CVD, or plasma-enhanced ALD. Next, following formation of the absorption layer, the transport layer is formed. Next, the transport layer and the absorption layer are activated by annealing. In one embodiment, the transport layer and the absorption layer are activated by thermal annealing, microwave energy (“microwave”) annealing, and annealing with the aid of plasma-excited species of hydrogen and/or oxygen (“plasma annealing”).

Next, an anti-reflective layer (or “coating”) may be provided on the first and second PV devices. The anti-reflective coating layer may be provided by any deposition technique known in the art. In one embodiment, the transport layer may operate as an anti-reflective layer.

Next, front and back electrodes may be provided. In one embodiment, front and back contacts may be provided via any deposition or metallization technique known in the art.

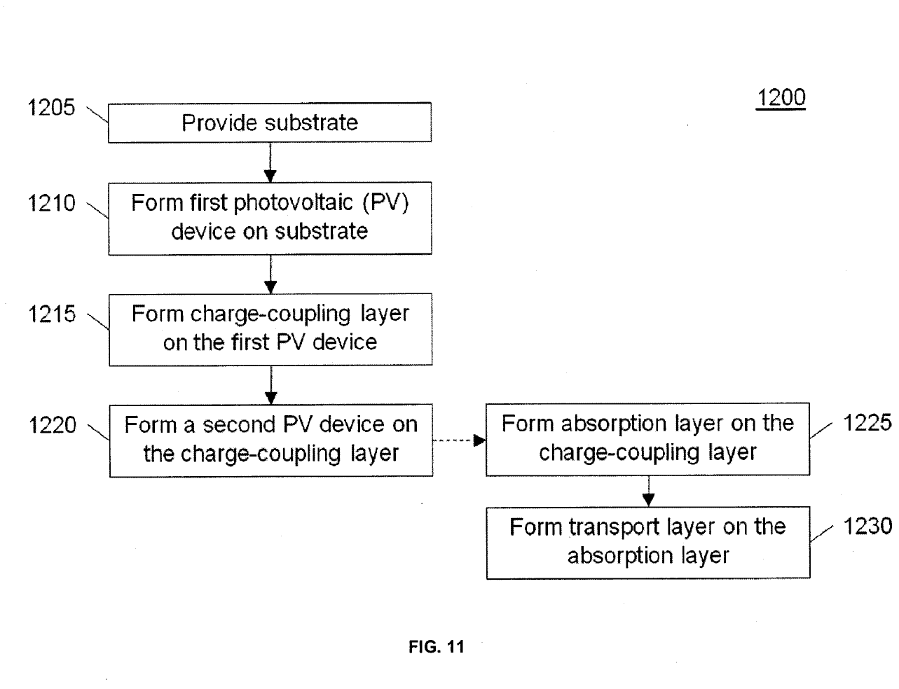

With reference to FIG. 12, a method 1200 for forming a photovoltaic (“PV”) cell is shown, in accordance with an embodiment of the invention. The method 1200 may be used to form any of the PV cells described herein, such as any of the PV cells of FIGS. 1-11. In a first step 1205, a substrate is provided. The substrate may include a metal, metal-containing material, a polymeric material, or a semiconductor-containing material, such as silica or quartz. In one embodiment, the substrate may include a single crystal or multi-crystal material, epiwafer or ribbon-shaped substrate, nanowire, nano-crystal or thin film. The substrate may be formed of a semiconductor-containing material, such as silicon.

In some implementations, a layer of a reflective material (configured to reflect light to the first and second PV devices) may be formed on the substrate. Next, in a second step 1210, a first PV device (e.g., PV device 115 of FIG. 1) is formed on the substrate or on the layer of reflective material. The first PV device may be formed by any deposition technique known in the art, such as ALD, CVD, plasma-enhanced ALD, plasma-enhanced CVD, PVD, or MBE. The first PV device may include a p-n or n-p junction, or a plurality of p-n and/or n-p junctions. The p-n and/or n-p junctions may be formed by introducing an n-type or p-type dopant into the first PV device via, for example, ion implantation or MBE or another deposition technique. In some cases, the formation of n-p and/or p-n junctions may be coupled with annealing to achieve a predetermined dopant depth-concentration profile. In other cases, the first PV device may be processed to form three-dimensional structures (see, e.g., FIGS. 9A-9E and accompanying description).

Next, in step 1215, a charge-coupling (or quantum coupling) layer is formed on the first PV device. The charge-coupling layer may include the semiconductor material of the first PV device. In one embodiment, the charge-coupling layer is formed by oxidizing a top portion of the first PV device with the aid of an oxidizing chemical (see above). In another embodiment, the quantum coupling layer is formed with the aid of a deposition technique, such as, for example, ALD or CVD. In another embodiment, the quantum coupling layer may be formed by an oxidation and/or deposition process followed by annealing, such as thermal annealing.

Next, in step 1220, a second PV device is formed on the charge-coupling layer. In one embodiment, the second PV device may be formed by any deposition technique known in the art, such as, for example, ALD or CVD. In another embodiment, the second PV device is formed by first forming a layer of a semiconductor-containing material on the charge-coupling layer and subsequently forming one or more p-n and/or n-p junctions in the layer of the semiconductor-containing material.

The second PV device may include one or more of a light transmission layer, an absorption layer and an electron transport layer. Next, in step 1225, after forming the charge-coupling layer, the second PV device may be formed by first providing an absorption layer. The absorption layer may be formed of a semiconductor-containing material. In some cases, the absorption layer may be processed to include one or more p-n and/or n-p junctions, such as an n-p or p-n junction. Next, in step 1230, a transmission layer is formed on the absorption layer. The transmission layer may be formed of a transparent or semi-transparent material. In some cases, the transmission layer may be formed of a material that does not appreciably interact with light to generate charge (e.g., electrons, holes). The transmission layer may be formed of an intrinsic (or undoped) or doped (n-type or p-type) semiconductor material. In some cases, the transmission layer may be a transport layer for directing photons of a predetermined energy or range or energies to the absorption layer, which absorbs photons of a predetermined energy or range of energies to generate electron-hole pairs (or electricity).

Next, a layer of anti-reflective material may be formed on one or both of the first and second PV devices. In one embodiment, the layer of anti-reflective material may be formed of a DARC material.

Devices, including cells and modules, and methods provided herein may be combined with or modified by other devices and methods. For example, devices and/or methods provided herein may be combined with, or modified by, devices and/or methods disclosed in U.S. Pat. No. 6,423,474 to Holscher (“USE OF DARC AND BARC IN FLASH MEMORY PROCESSING”), U.S. Pat. No. 7,560,390 to Sant et al. (“MULTIPLE SPACER STEPS FOR PITCH MULTIPLICATION”) and U.S. Pat. No. 7,572,572 to Wells (“METHODS FOR FORMING ARRAYS OF SMALL, CLOSELY SPACED FEATURES”), which are entirely incorporated herein by reference. As another example, devices and/or methods provided herein may be combined with, or modified by, the teachings of Green et al., “Solar Cell Efficiency Tables”, Progress in Photovoltaics Research and Applications, V17, p 85 (2009); M. A. Green, “The path to 25% Silicon Solar Cell Efficiency”, Progress in Photovoltaics Research and Applications, V17, p 183 (2009); Yoon et al., “Ultra-thin silicon solar micro cells”, Nature Materials, V7, p 909 (2008); Kelzenberg et al., “Enhanced absorption and carrier collection in Si wire arrays for photovoltaic applications”, Nature Materials, V9, p 239 (2010); King et al., “40% Efficient Metamorphic GaInP/GaInAs/Ge multi junction solar cells”, Applied Physics Letters, V90, p 183516 (2007); B. O'Regan and M. A. Gratzel, “A high efficiency solar cell based on dye sensitized colloidal TiO₂ films”, Nature 353, p 737 (1991); Bai et al., “High performance dye-sensitized solar cells based on solvent-free electrolytes produced from eutectic melts”, Nature Materials, V7, p 626 (2008); Cao et al., “Engineering light absorption in semiconductor nanowire devices”, Nature Materials, online publication, Jul. 5, 2009; Fan et al., “Three Dimensional nano pillar array photovoltaics on low cost and flexible substrates”, Nature Materials, p 1 (2009); M. A. Green, “Study of silicon quantum dot p-n and p-i-n junction devices on c-Si substrates”, Proc. of the Conference on Optoelectronics and Microelectronics Materials, p 316 (2008); Tisdale et al., “Hot electron transfer from semiconductor nano crystals”, Science, V328, p 1543 (2010); and E. Yablonovitch and G. D. Cody, “Intensity enhancement in textured optical sheets for solar cells”, IEEE Trans. on Electron Devices, V29, p 300, (1982), which are entirely incorporated herein by reference.

It should be understood from the foregoing that, while particular implementations have been illustrated and described, various modifications may be made thereto and are contemplated herein. It is also not intended that the invention be limited by the specific examples provided within the specification. While the invention has been described with reference to the aforementioned specification, the descriptions and illustrations of the preferable embodiments herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents.

1. A photovoltaic cell, comprising:
a first photovoltaic device having a first energy band gap;
at least one charge-coupling layer adjacent the first photovoltaic device; and
a second photovoltaic device adjacent the at least one charge-coupling layer, the second photovoltaic device having a second energy band gap.

2. (canceled)

3. The photovoltaic cell of claim 1, wherein the at least one charge-coupling layer includes an electrically insulating, semi-insulating and/or semiconducting materials.

4. The photovoltaic cell of claim 1, wherein the first photovoltaic device and the second photovoltaic device are quantum mechanically coupled with the aid of the at least one charge-coupling layer.

5. (canceled)

6. The photovoltaic cell of claim 1, wherein the first photovoltaic device includes a first layer adjacent a second layer, the first layer having a photon transmitting and electron and/or hole transport material, the second layer having a material for absorbing photons and generating electricity.

7.-8. (canceled)

9. The photovoltaic cell of claim 1, wherein the first photovoltaic device includes a light transmission layer adjacent a photo absorption layer, the light transmission layer formed of an insulating and/or semi-insulating material.

10.-17. (canceled)

18. The photovoltaic cell of claim 1, wherein the first energy band gap is greater than or equal to the second energy band gap.

19. The photovoltaic cell of claim 1, wherein the first photovoltaic device comprises one or more of a semiconductor, semi-insulator, and insulator.

20. The photovoltaic cell of claim 1, wherein the second photovoltaic device comprises one or more of a semiconductor and semi-insulator.

21. The photovoltaic cell of claim 1, wherein the first photovoltaic device comprises one or more of quantum dots and quantum wells.

22.-33. (canceled)

34. The photovoltaic cell of claim 1, wherein the first photovoltaic device includes one or more of dyes.

35. The photovoltaic cell of claim 34, wherein the first photovoltaic device includes one or more charge-coupling layers.

36. The photovoltaic cell of claim 34, wherein the one or more dyes are embedded in a semiconductor, semi-insulating or insulating material.

37. The photovoltaic cell of claim 34, wherein the one or more dyes are provided in a layer of dyes adjacent a layer of semiconducting material, the layer of semiconducting material between the layer of dyes and the at least one charge-coupling layer.

38. The photovoltaic cell of claim 1, further comprising an other charge-coupling layer adjacent the second photovoltaic device and a third photovoltaic device adjacent the other charge-coupling layer.

39. The photovoltaic cell of claim 38, wherein the first photovoltaic devices and/or third photovoltaic device include one or more charge-coupling layers.

40. A photovoltaic module comprising a plurality of photovoltaic solar cells, an individual photovoltaic solar cell of the plurality of cells according to claim 1, wherein individual photovoltaic solar cells of the module are electrically floating or electrically coupled to one another in series or parallel.

41. A photovoltaic cell, comprising:
a first photovoltaic device having a light transmission layer adjacent a photon absorption layer, the photon absorption layer configured to generate charge upon exposure to photons; and
at least one quantum coupling layer adjacent the first photovoltaic device, the at least one quantum coupling layer configured to couple charge in an electrically conductive layer or second photovoltaic device adjacent the at least one quantum coupling layer to charge in the absorption layer.

42.-44. (canceled)

45. The photovoltaic cell of claim 41, further comprising a third photovoltaic device adjacent the second photovoltaic device and at least one other quantum coupling layer between the first photovoltaic device and third photovoltaic device.

46. The photovoltaic cell of claim 41, wherein the photon absorption layer includes one or more dyes.

47. (canceled)

48. A photovoltaic cell array, comprising:
a plurality of photovoltaic cells, each individual photovoltaic cell of the plurality of photovoltaic cells comprising a first photovoltaic device having a first energy band gap, at least one charge-coupling layer adjacent the first photovoltaic device, and a second and/or third photovoltaic device adjacent the at least one charge-coupling layer, the second and/or third photovoltaic device having a second and/or third energy band gap, wherein said plurality of photovoltaic cells are electrically floating cells or interconnected in series or parallel.

49.-56. (canceled)
